(19) United States
(12) Patent Application Publication
(10) Pub. No.: US 2007/0098900 A1
(43) Pub. Date: May 3, 2007

(54) Media providing non-contacting formation of high contrast marks and method of using same, composition for forming a laser-markable coating, a laser-markable material and process of forming a marking

(75) Inventors: Akira Abe, Fort Lee, NJ (US); Janet M. Carlock, Wayne, NJ (US); Yue Chen, Edison, NJ (US); Hailing Duan, Montville, NJ (US); Toshio Hara, Fujinomiya-shi (JP); Haixing Wan, Ramsey, NJ (US); Tsutomu Watanabe, Fuji-shi (JP)

Correspondence Address: BUCHANAN, INGERSOLL & ROONEY PC, POST OFFICE BOX 1404, ALEXANDRIA, VA, 22313-1404, US

(73) Assignees: FUJI HUNT PHOTOGRAPHIC CHEMICALS, INC.; FUJI PHOTO FILM CO., LTD.

(21) Appl. No.: 11/393,754

(22) Filed: Mar. 31, 2006

Related U.S. Application Data
(63) Continuation-in-part of application No. 11/267,322, filed on Nov. 7, 2005, now abandoned.
(63) Continuation-in-part of application No. 11/296,348, filed on Dec. 8, 2005, now abandoned.
(60) Provisional application No. 60/625,122, filed on Nov. 5, 2004.
(60) Provisional application No. 60/634,099, filed on Dec. 8, 2004.

(51) Int. Cl. B05D 5/00; H01L 21/00; B05D 1/36

(52) U.S. Cl. 427/261; 438/460; 438/799

(57) ABSTRACT

A laser markable media that can provide superior mark quality with high contrast, high resolution, and a high degree of quality consistency, and that does not rely on physical damages to the material integrity on the exposed area. The laser markable media further provides a balanced performance between good media storage stability, heat resistance and optimum sensitivity to laser exposure. Also disclosed is a laser markable media that has a high degree of transparency to satisfy a wider range of application requirements than found in the prior art and a method of using the media.

### CROSS-REFERENCE TO RELATED APPLICATIONS

This application is a continuation-in-part of U.S. application Ser. No. 11/267,322 filed Nov. 7, 2005, which claims the benefit of U.S. Provisional Application No. 60/623,122 filed Nov. 5, 2004. This application is also a continuation-in-part of U.S. application Ser. No. 11/296,348 filed Dec. 8, 2005, which claims the benefit of U.S. Provisional Application No. 60/634,099 filed Dec. 8, 2004. The contents of the above applications are herein incorporated by reference.

### BACKGROUND

Product and package labeling is becoming increasingly important in various industries, and it is generally beneficial to provide clearly visible, sharp, high contrast marks. In some applications, it can be beneficial to provide color images rather than black and white images.

Among conventional processes, printing, embossing, stamping and label application are predominant means for product marking. However, it can be desirable in a particular application to allow for frequent information changes, such as individualized product identification, coding, production date, lot number, or expiration date marking. Accordingly, there is a need for marking means which enables the rapid change of content.

Various printing technologies are used for such application, including direct thermal printing on self-adhesive labels, thermal dye-transfer printing, inkjet printing, embossing or stamping, among others. However, production throughput is often limited due to bottlenecks in the printing speed, particularly when physical contact with each product or label is necessary, such as thermal printing (either direct or dye transfer), drop-on-demand (DOD) type inkjet printing, embossing or stamping. In addition, since these marking technologies rely on physical contact, they are not suitable for marking on products with un-even surfaces. Thermal printing systems also have other disadvantages, such as dirt accumulation on the thermal head and wearing of the contacting surface, which degrades marking quality and readability.

For a non-impact high speed marking application, continuous inkjet (CIJ) technology is also frequently used. However, CIJ technology has problems of frequent nozzle clogging and VOC issues for solvent-based ink systems, or mark smearing problem for aqueous-based ink system, due to slow drying speed of the marks on non-absorbing surfaces, such as plastic films, metal or plastic containers, and the like. Another disadvantage of CIJ technology is its low resolution and low contrast in terms of marking quality. This especially becomes a problem for bar-code printing.

Methods are known in the art for non-contacting rapid marking using focused beams of electromagnetic wave of specific wavelengths and intensity, such as laser beams, which is commonly known as “laser marking”. However, one key disadvantage of laser marking is that it requires strong interaction of the laser beam with the material to be marked, to yield significant color or density changes on unmarked areas. The difficulty is that many packaging materials, such as plastic films or containers, metal cans or glass bottles, either do not have sufficient interaction with laser beam (particularly with low power and/or long wavelength laser beams), or the interaction does not yield significant contrast change on the material to yield high quality marks, or in the case that the interaction is strong, it causes direct damages on the material itself.

To enhance the laser beam-material interaction, energy absorbing compounds have been proposed either to be dispersed into the packaging material to be marked on, or to be mixed into a coating composition which in turn is coated on the surface of the material to be marked on. Typical examples of such technology are inorganic based phyllosilicates, metal oxides and silicates compounds, such as talc, kaolin, sericite, mica or metal-oxide coated mica, titanium oxides, tin oxides, iron oxides, or oxides of Sb, As, Bi, Cu, Ga, Ge Si, and the like, as disclosed in U.S. Pat. Nos. 6884289, 6855910, 677683, 6727308, 6719837, 6693657, 6689205, 6545065, 6521688, 6444068, 6376577, 6291551, 6214917, 5977514, 5928780, 5866644, 5855969, 5576377, 5030551, Japanese Patent Publication Nos. 2003/277570, and World Patent Document No. WO 2004/050766, WO 01/00719 and WO 03/006558.

However, even with the enhanced interaction between laser beam and material, mark density or contrast are often too weak to become satisfactory commercial products, since it relies on charring or decomposition of the material to be marked on, to either form carbon-rich structures in the material as dark marks, or to generate trapped micro-bubbles (from decomposed material) to form foaming structure in the material as white marks. These mark formation mechanisms often yield poor quality marks because many polymer materials are difficult to carbonize without excessive burning, vaporizing, or complete decomposition, which causes damage to material integrity. Another disadvantage of relying on inorganic laser absorption substances to improve the problem of laser sensitivity is the haziness these additives bring into the material to be marked on, observed as a reduced transparency of the media material. Reduced transparency limits the use of laser markable materials to a narrower range of commercial applications.

To enhance mark contrast and color, it is known in the art that pigments of organo-metallic complexes, inorganic oxides or salts, or carbon black pigment could be used as additives to be dispersed into the packaging material, or to be mixed into a coating composition which, in turn, is coated on the surface of the material to be marked. In addition, dual coating layers of contrast colors is also proposed, in which the top coating is to be evaporated (ablated) by the laser marking, and thus expose the bottom coating of contrast color. Typical examples of compounds used in these technologies include organo-metallic complex such as copper phthalocyanines, amine molybdate, or colored metal oxide and hydroxide, or metal phosphate/oxide mixed-phase pigments, sulfide and sulfide/selenium pigments, carbonate pigments, chromate and chromate/molybdate mixed-phase pigments, complex-salt pigments and silicate pigments, as disclosed in U.S. patents and U.S. published patent application nos. 2005/0032957, 6888095, 6855910, 6284184, 6207240, 6139614, 6022905, 5840791, 5667580, 5626966. 5576377, 4861620 and 4401992.

However, major disadvantages of pigment-based laser marking formulation include the problem of the large particle size of the pigments relative to the desired substrate or coating thickness, and uneven distribution of these solid particles in the media. These problems result in uneven marks and coating coverage, or excessive burning in the marking areas causing damage to media integrity. In addition, some of the currently known marking pigments contain heavy metals that have environmental disadvantages. For laser marking based on the ablation approach, excessive releasing of ablated material or debris into the ambient environment is a significant disadvantage; not only are hazardous materials released into the environment, but also it requires frequent cleaning of the lens on the laser marking head to remove the accumulated fragments or debris released from the ablated marking material. Another disadvantage of the ablation approach is it requires a large laser energy dose, strong enough to completely vaporize the coated layer on the material to be marked. This either leads to slower marking speed which means lower productivity, or more equipment and operation spending for a higher powered laser system.

Dye-based laser marking formulations can avoid the above disadvantages, and offer better marking quality with much higher contrast, even at a much lower laser energy dose. Dye based marking technology developed for conventional contacting thermal printing has been proposed for laser marking applications. For example, JP 2001-246860 discloses the use of a thermal recording material which contains an electron donor dye precursor and a urea-urethane developer, and U.S. Pat. No. 5413629 discloses a method of preparing a laser markable material by using an ink which contains an electron donor dye precursor and an electron acceptor developer in the printing process.

However, these systems that rely on conventional direct thermal printing technology have disadvantages of poor long-term storage stability or heat resistance, due to the nature of the energy delivery means in direct thermal printing, which relies on contacting heat transfer to rapidly trigger color formation reaction near the contacting interface, and thus requires the reactive media changing color at a threshold temperature of about 80° C. to about 110° C. On the other hand, for packaging and labeling applications, the media often requires wide tolerance over broad temperature ranges and with a long exposing period. In these applications, the long-term storage stability or heat resistance of direct thermal media are often not sufficient, and undesired fogging could result during storage or product transportation.

Another significant disadvantage of dye-based media relying on direct thermal printing technology is its susceptibility towards undesired chemical exposure, especially exposure to acid and base solutions or organic solvents. However, for certain packaging and labeling applications, the coated substrate often requires strong resistance towards various chemical attacks. For example, in typical label printing, solvent based flexographic inks are frequently use, or in some cases a solvent-based primary coat on label films is applied to enhance the leveling and ink adhesion to the film. In both cases, organic solvents in these formulation often cause undesired color, opacity or density changes on above said imaging layer, due to destabilization of the dye-developer system.

To improve the media stability and enhance heat resistance of dye-based laser markable media, U.S. Pat. No. 5,691,757 and Japanese patent JP3391000 disclose laser markable compositions using a high melting point developer, above 200° C., to avoid losing marking sensitivity from using high melting point developer. Such combination leads to a very high mark formation threshold temperature, at least in the range of 200-250° C. or even higher. One problem of this approach is the risk of decomposition of the polymer media during the high temperature marking process, and releasing of undesired chemical vapor as “smoke”, which is indeed frequently observed with those laser marking methods relying on charring of the material to be marked. In addition, for such a high temperature marking media, either higher powered laser marking equipment becomes necessary, or slower marking speed, and thus lower productivity, has to be accepted.

To prevent releasing of undesired chemical vapor, the idea of transparent “cover sheet” has been suggested in the prior art. U.S. Pat. No. 5,843,547 discloses a method to make a multilayered laser markable label, in which at least one layer of transparent protective film material with a transparent adhesive composition is stacked and adhered to the top of a laser markable media. The laser marking process is applied through the transparent “cover sheet” to form marks in the underneath laser markable media. If desired by application, the top transparent “cover sheet” along with the transparent adhesive composition can be peeled off from the laser markable media after marking. Similar structures are disclosed in U.S. Pat. No. 5,340,628 and Japanese patent 3391000, except that the laser markable layers are both relying on dye-based thermal printing technology instead of inorganic pigments, and in the case of Japanese patent 3391000, as already described above, a high melting point developer is used in conjunction with inorganic laser absorption additives.

While the release of decomposed chemical vapor during laser marking can be prevented by the approaches in these prior arts, the disadvantage of the method disclosed in U.S. Pat. No. 5,843,547 is its inorganic pigment based laser imaging media, which tends to have inferior mark quality, poor contrast and consistency, as compared to dye-based marking systems. The disadvantage of the approach disclosed in U.S. Pat. No. 5,340,628 is its poor long-term storage stability or heat resistance which are inherited from its origin of conventional thermal imaging media. The disadvantage of the approach disclosed in Japanese patent 3391000 is its requirement of >200° C. mark formation temperature, which could lead to decomposition of certain polymer materials used for the transparent “cover sheet” during high temperature marking process, releasing undesired chemical vapor; or at least it could introduce significant physical distortion to the marking media due to the residue thermal stress, since the mark formation temperature will be well above the glass transition temperature, T_{g}, of most of the polymer materials disclosed in that patent. Finally, all three approaches suffer from the disadvantages of high level of haziness described earlier, and thus reduced transparency of the mark formation media, common to all laser markable coatings containing solid dispersed species.

It is accordingly noted that in the methods and composition of the prior art described above, it is very difficult to simultaneously achieve good mark quality, high contrast, high storage stability or heat resistance of a marking material, while at the same time maintaining good laser sensitivity and eliminating undesired chemical vapor release during marking process.

Another disadvantage of employing conventional laser ablation means is that it can require strong interaction of the marking substrate with the laser beam to yield significant color or density changes in comparison with unmarked areas. Packaging materials such as plastic films, containers and glass bottles, can lack sufficient interaction with laser beam energy, the interaction can fail to yield sufficient contrast changes on the material, and/or the interaction can cause undesirable damage to the substrate surface.

A coating can be formed on the substrate that is capable of absorbing energy of a laser beam to yield visible marks on the coated substrate. This type of laser-markable coating can contain pigments, dyes, binders, as well as other coating additives. The coating composition can contain a binder which functions substantially as a film forming agent. Besides being utilized for its film-forming function, binders can be used in various applications to obtain special effects in laser-markable coating compositions.

Use of conventional binders can lead to various adverse effects which can be described as interference mark effects. The formation of such interference marks can contribute to low mark quality of the marked material. Interference mark effects can be manifested in several different ways. For example, a whiteness, opacity, or haziness can occur in the area near laser exposure, which can be visible with the naked eye. A conventional binder can undergo a physical change when exposed to a laser beam to produce microvoids, bubbles, crosslinks, fine particulates and/or inclusions, which can result in opacity or otherwise degradation of the mark. The interference marks can lead to low mark density, poor color purity, and/or visually unsharp/distorted images in the marked region of the material. Machine and/or human readability can be reduced when the intended marks to be formed by laser exposure are lower in quality than required.

### BRIEF DESCRIPTION OF THE DRAWINGS

FIGS. 1-5 are cross-sections of illustrative media of the invention.

FIG. 6 shows an image of two exemplary coatings exposed to a CO₂ laser.

FIGS. 7A to 7H are images of various exemplary coatings exposed to a CO₂ laser.

Figures 8A to 8E are images of various exemplary coatings exposed to a CO₂ laser.

FIGS. 9A to 9H are images of various exemplary coatings exposed to a CO₂ laser.

### SUMMARY

A first objective of the present invention is to provide a media that can be marked with a laser provide superior mark quality with high contrast, high resolution, and a high degree of quality consistency, and that does not rely on physical damage to the material integrity on the exposed area, such as ablation, charring, or trapping of gaseous bobbles released from chemical decomposition of coating ingredients.

A second objective of the present invention is to provide a media that has a balanced performance between good media storage stability or heat resistance and optimum sensitivity to laser exposure.

A third objective of the present invention is to provide a laser markable media that have high degree of transparency to satisfy wider range of application needs.

Yet, another objective of the present invention is to provide laser markable media configurations that do not release decomposed chemical vapors or debris during laser marking process, and that can isolate the mark formation layer from direct exposure to the environment, and therefore the mark formation layer is protected from direct mechanical abrasions or chemical attacks.

A further objective of the present invention is to provide a method of using the media.

According to one aspect, a laser markable media is provided with the following features: (1) the mark formation layer comprises at least one kind of electron donor dye precursor encapsulated or isolated by a polymer having a T_{g} of from about 120° C. to about 190° C., wherein at least about 80% w/w of said dye precursor has a solubility of higher than 10 g/100 g of ethyl acetate and approximately 90% of the total volume of said dye precursor particles have a diameter of from about 0.2 μm to about 5 μm, and (2) the laser markable material is configured in such a way that the said mark formation layer is located behind a protective substrate or coating, through which the laser irradiation will be applied, and the said protective substrate material is significantly transparent to the wavelength of the laser intend to be used and having an on-set pyrolysis temperature of at least 200° C.

In accordance with another aspect, a coating composition for forming a laser-markable material is provided, comprising electron donor dye precursor particles encapsulated with a polymer having a glass transition temperature, T_{g}, of from about 150° C. to about 190° C., wherein at least about 90% of the total volume of the dye precursor particles have a diameter from about 0.2 μm to about 5 μm.

In accordance with another aspect, a laser-markable material is provided comprising a coating layer, wherein the coating layer comprises electron donor dye precursor particles encapsulated with a polymer having a glass transition temperature, T_{g}, of from about 150° C. to about 190° C., wherein at least 90% of the total volume of the dye precursor particles have a diameter from about 0.2 μm to about 5 μm.

In accordance with another aspect, a composition for forming a laser-markable coating is provided, comprising: (a) a first component of a color-forming agent, wherein upon exposure to a laser the first component is capable of reacting with a second component of the color-forming agent to generate a color; and (b) a binder comprising a substituted or unsubstituted polyurethane.

In accordance with another aspect, a laser-markable material is provided, comprising: (a) a coating comprising a substituted or unsubstituted polyurethane compound; and (b) a laser-markable layer, wherein the coating is in contact with the laser-markable layer.

In accordance with another aspect, a process of forming a marking by laser exposure is provided, comprising applying a composition comprising the coating composition to a substrate to form a coating, and exposing at least a part of the coating to a laser.

In accordance with a further aspect, a process of forming a marking by laser exposure is provided, comprising combining the coating composition with a second composition comprising the second component, applying the resulting composition to a substrate to form a coating, and exposing at least a part of the coating to a laser.

### DETAILED DESCRIPTION

A. Composition of the Mark Formation Layer

To achieve the first three objectives of the present invention, the composition of the mark formation layer comprises the following key elements: an electron donor dye precursor preferably micro-encapsulated within a polymer of specific T_{g} range, an electron acceptor compound which can react with the electron donor dye precursor to turn it into a dye with a strong absorption in the wavelength range of visible spectrum, and a polymer dispersion media in which both species are dispersed and coated in such way that they are in close proximity of reaction lengths from each other.

Electron Donor Dye Precursor

An electron donor dye precursor that can be preferably used in the present invention is not particularly limited as long as it is substantially colorless, and is preferably a colorless compound that has such a nature that it colors by donating an electron or by accepting a proton from an acid. A particularly preferred structural feature. in the backbone of the electron donor dye precursor includes a ring structure which is subjected to ring opening reaction or cleavage in the case where it is in contact with an electron accepting compound. Typical examples of such structural feature are a lactone, a lactam, a saltone, or a spiropyran, among others.

Examples of the electron donor dye precursor include a triphenylmethane phthalide series compound, a fluorane series compound, a phenothiazine series compound, an indolyl phthalide series compound, a leucoauramine series compound, a rhodamine lactam series compound, a triphenylmethane series compound, a triazene series compound, a spiropyran series compound, a fluorene series compound, a pyridine series compound, and a pyradine series compound.

Specific examples of the fluorane series compound include the compounds described in U.S. Pat. Nos. 3,624,107, 3,627,787, 3,641,011, 3,462,828, 3,681,390, 3,920,510 and 3,959,571. Specific examples of the fluorene series compound include the compounds described in Japanese Patent Application No. 61-240989. Specific examples of the spiropyran series compound include the compounds described in U.S. Pat. No. 3,971,808. Specific examples of the pyridine series and pyradine series compounds include the compounds described in U.S. Pat. Nos. 3,775,424, 3,853,869 and 4,246,318.

Among the fluorane series, the compounds represented by following structural formula (1) are preferable because these can be incorporated into the microcapsules in very high concentration and hence can provide high mark density. 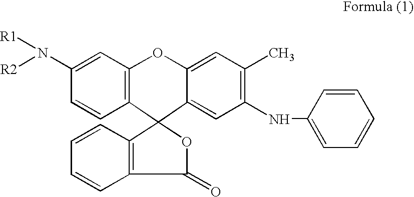
wherein R1 and R2 are each independently selected from hydrogen, C₁-C₈ alkyl, unsubstituted or C₁-C₄ alkyl- or halogen-substituted C₄-C₇ cycloalkyl, unsubstituted phenyl or C₁-C₄ alkyl-, hydroxyl- or halogen-substituted phenyl, C₃-C₆ alkenyl, C₁-C₄ alkoxy, phenyl-C₁-C₄ alkyl, C₁-C₄ alkoxy-C₁-C₄ alkyl and 2-tetrahydrofuranyl, or R1 and R2 together with the linking nitrogen atom are an unsubstituted or C₁-C₄ alkyl-substituted pyrrolidino, piperidino, morpholino, thiomorpholino or piperazino ring. In a preferred embodiment, RI can represent C₄H₉ and R2 can represent C₂H₅.

Among the fluorene series, a 2-arylamino-3-(H, halogen, alkyl or alkoxy-6-substituted aminofluorane) is preferably exemplified. Specific examples thereof include 2-anilino-3-methyl-6-diethylaminofluorane, 2-anilino-3-methyl-6-N -cyclohexyl-N-methylalfluorane, 2-p-chloroanilino-3-methyl-6-dibutylaminofluorane, 2-anilino-3-methyl-6-dioctylaminofluorane, 2-anilino-3-chloro-6-diethylaminofluorane, 2-anilino-3-methyl-6-N-ethyl-N -isoamylaminofluorane, 2-anilino-3-methyl-6-N-ethyl-N-dodecylaminofluorane, 2-anilino-3-methoxy-6-dibutylaminofluorane, 2-o-chloroanilino-6-dibutylaminofluorane, 2-p-chloroanilino-3-ethyl-6-N-ethyl-N -isoamylaminofluorane, 2-o-chloroanilino-6-p-butylanilinofluorane, 2-anilino-3-pentadecyl-6-diethylaminofluorane, 2-anilino-3-ethyl-6-dibutylaminofluorane, 2-o -toluidino-3-methyl-6-diisopropylaminofluorane, 2˜anilino-3-methyl-6-N-isobutyl -N-ethylaminofluorane, 2-anilino-3-methyl-6-N-ethyl-N -tetrahydrofurfurylaminofluorane, 2-anilino-3-chloro-6-N-ethyl -N˜isoamylaminofluorane, 2-anilino-3-methyl-6-N-methyl-N -gamma.ethoxypropylaminofluorane, 2-anilino-3-methyl-6-N-ethyl-N-.gamma -ethoxypropylaminofluorane and 2-anilino-3-methyl-6-N-ethyl-N-.gamma -propoxypropylaminofluorane.

Specific examples of the phthalide series compound include the compounds described in U.S. Pat. Nos. Re. 23024, 3491111, 3491112, 3491116, and 3509174. Among the phthalide series, the compounds represented by following structural formula (2) are most preferable because it can be incorporated into the microcapsules at a very high concentration and can provide high mark density. 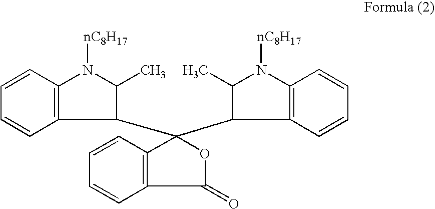
Another preferred compound is represented by formula (3) which is as follows.

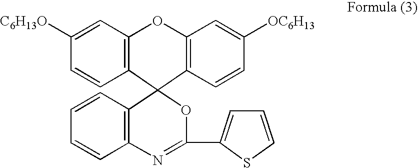

A preferable embodiment of the present invention is that the solubility of the said electron donor dye precursor is higher than about 10 g/100 g in ethyl acetate, more preferably is higher than about 15 g/100 g in ethyl acetate, and most preferably is higher than about 18 g/100 g in ethyl acetate.

A preferable embodiment of the present invention is that more than about 80% by weight of the electron donor dye precursors are compounds represented by structural formula (1) or formula (2), and a more preferable embodiment is that more than about 90% by weight are said compounds and a most preferable embodiment is that about 100% by weight are said compounds.

Micro-Encapsulation

It is preferred that the electron donor dye precursor in the composition of the present invention be used after being formed into a microcapsule, preferably via a surface polymerization process. For example, the surface polymerization process can be employed such that the electron donor dye precursor for forming a core of the microcapsules, is dissolved or dispersed in a hydrophobic organic solvent to prepare an oily phase. The oily phase can then be mixed with an aqueous phase obtained by, for example, dissolving a water-soluble polymer in water, and can then be subjected to emulsification and dispersion by using, for example, a homogenizer. This can be followed by heating, so as to conduct a polymer-forming reaction at the interface of the oily droplets, whereby a microcapsule wall of a polymer substance can be formed.

Specific examples of the polymer capsule materials include, for example, polyurethane, polyurea, polyamide, polyester, polycarbonate, a urea-formaldehyde resin, a melamine resin, polystyrene, a styrene-methacrylate copolymer and a styrene-acrylate copolymer. Among these, polyurethane, polyurea, polyamide, polyester and polycarbonate are preferred, and polyurethane and polyurea are particularly preferred.

For example, in the case where polyurea is used as the capsule wall material, the microcapsule wall can be easily formed by reacting a polyisocyanate, such as diisocyanate, triisocyanate, tetraisocyanate or a polyisocyanate prepolymer, with a polyamine, such as diamine, triamine or tetramine, a prepolymer having two or more amino groups, piperazine or a derivative thereof, or a polyol, in the aqueous phase by the interface polymerization process.

A composite wall formed with polyurea and polyamide or a composite wall formed with polyurethane and polyamide can be prepared in such a manner that, for example, a polyisocyanate and a secondary substance for forming the capsule wall through reaction therewith (for example, an acid chloride, a polyamine or a polyol) are mixed with an aqueous solution of a water-soluble polymer (aqueous phase) or an oily medium to be encapsulated (oily phase), and subjected to emulsification and dispersion, followed by heating. The production process of the composite wall formed with polyurea and polyamide is described in detail in JP-A-58-66948, the contents of which are incorporated by reference. For additional detailed description of such process, refer to known published literatures, such as “Polyurethane Handbook” written by Keiji Iwata, and published by Nikkan Kogyo Shimbun, Ltd. (1987) and “Polyurethane Handbook” edited by Dr. Gütnter Oertal, and published by Hanser Gardner Publications, Inc. (2^{nd} ed., 1993), the contents of which are incorporated by reference.

As an exemplary polyisocyanate compound, a compound having an isocyanate group of three or more functional groups can be used, and a difunctional isocyanate compound can be used in combination therewith. For example, the following exemplary compounds can be used: a diisocyanate such as xylene diisocyanate or a hydrogenated product thereof, hexamethylene diisocyanate or a hydrogenated product thereof, tolylene diisocyanate or a hydrogenated product thereof and isophorone diisocyanate; a dimer or a trimer thereof (burette or isocyanaurate); a compound having polyfunctionality as an adduct product of a polyol, such as trimethylolpropane, and a difunctional isocyanate, such as xylylene diisocyanate; a compound of an adduct product of a polyol, such as trimethylolpropane, and a difunctional isocyanate, such as xylylene diisocyanate, having a polymer compound, such as polyether having an active hydrogen, such as polyoxyethylene oxide, introduced thereto; and a formalin condensation product of benzeneisocyanate.

The compounds described in JP-A-62-212190, JP-A-4-26189, JP-A-5-317694 and Japanese Patent Application No. 8-268721 can be used, the contents of which are herein incorporated by reference. Specific examples of the polyol and/or the polyamine added to the aqueous phase and/or the oily phase as one constitutional component of the microcapsule wall through the reaction with the polyisocyanate include propylene glycol, glycerin, trimethylolpropane, triethanolamine, sorbitol and hexamethylenediamine. In the case where a polyol is added, a polyurethane wall can be formed.

In the present invention, the conditions for the microencapsulation reaction are set so that at least about 90% of the total volume of said electron donor dye precursor particles have an average particle diameter of the microcapsules that are formed of between about 0.2 to about 12 μm, preferably between about 0.3 μm and about 5 μm, and most preferably between about 0.3 μm and about 2 μm. The thickness of the microcapsule wall can be any suitable thickness, for example, from about 0.01 μm to about 0.3 μm.

The microcapsule material and microencapsulation reaction can be carefully selected and controlled so that the microcapsule wall has a glass-transition temperature, T_{g}, of from about 120° C. to about 190° C., preferably from about 150° C. to about 190° C., more preferably from about 150° C. to about 180° C., more preferably from about 160° C. to about 180° C., and most preferably from about 165° C. to about 175° C. The T_{g} of the microcapsule wall can be measured by any suitable means, for example, by using conventional differential thermal analysis methods such as DSC (Differential Scanning Calorimeters) or DDSC (Dynamic DSC), which measure specific heat (Cₚ) change over different temperature ranges. Equipment which can be used for such measurements include Perkin Elmer Diamond DSC, Sapphire DSC, HyperDSC™, and TA Instruments Q-series.

For example, to obtain the above-described characteristics, specific reaction conditions for microcapsule preparation can be selected and controlled. These conditions can include the emulsification process of the electron donor dye precursor, addition rates and amounts of the polyisocyanate and polyamine to form the microcapsule wall, and/or mixing and reaction temperature, time, and agitation. In the reaction, the reaction rate can be increased, for example, by maintaining a high reaction temperature and/or by adding an appropriate polymerization catalyst.

Particle size of the microcapsules in the suspension can be measured using any suitable means, for example, by diluting the suspension into aqueous solution and using a laser scattering method based on Mie-scattering theory to measure the particle size and distribution. Equipment which can be used for such measurement include Horiba's LA series, Beckman Coulter's LS series or Malvern Instruments' Mastersizer series.

The microcapsule wall may further contain, depending on necessity, a metal-containing dye, a charge adjusting agent such as nigrosin, and other arbitrary additive substances. These additives may be contained in the capsule wall if added before or during wall formation or added at other arbitrary times as required. In order to adjust the charging property of the surface of the capsule wall, a monomer, such as a vinyl monomer, may be graft-polymerized depending on necessity.

Furthermore, in order to make a microcapsule wall having excellent substance permeability at desired marking temperature and to obtain superior mark quality of high coloring effect, it is preferred to use a plasticizer that is suitable for the polymer of the chosen wall material. The plasticizer preferably has a melting point of about 50° C. or more, more preferably about 120° C. or more. Among plasticizers, materials in a solid state at room temperatures can be preferably selected.

For example, in the case where the wall material comprises polyurea or polyurethane, a hydroxyl compound, a carbamate compound, an aromatic alkoxy compound, an organic sulfonamide compound, an aliphatic amide compound, and an arylamide compound are preferably used as a plasticizer.

The core of the microcapsule can be prepared by dissolving the electron onor dye precursor compound in a hydrophobic organic solvent having a boiling oint of preferably from about 100 to about 300° C. so as to form the oily phase. The hydrophobic organic solvent can contain one or more compounds. Specific examples of the solvent include an ester compound, dimethylnaphthalene, diethylnaphthalene, diisopropylnaphthalene, dimethylbiphenyl, diisopropyldiphenyl, diisobutylbiphenyl, 1-methyl-1-dimethylphenyl-2-phenylmethane, 1-ethyl-1-dimethylphenyl-1-phenylmethane, 1-propyl- 1-dimethylphenyl- 1-phenylmethane, triarylmethane (such as tritoluylmethane or toluyldiphenylmethane), a terphenyl compound (such as terphenyl), an alkyl compound, an alkylated diphenyl ether (such as propyldiphenyl ether), hydrogenated terphenyl (such as hexahydroterphenyl) and diphenylterphenyl. These hydrophobic organic solvents may be used alone or in combinations of two or more.

An ester compound can be preferably used, for example, from the standpoint of emulsification stability of the emulsion dispersion. The ester compound can include, for example, a phosphate, such as triphenyl phosphate, tricresyl phosphate, butyl phosphate, octyl phosphate or cresylphenyl phosphate; a phthalate, such as dibutyl phthalate, 2-ethylhexyl phthalate, ethyl phthalate, octyl phthalate or butylbenzyl phthalate; dioctyl tetrahydrophthalate; a benzoate, such as ethyl benzoate, propyl benzoate, butyl benzoate, isopentyl benzoate or benzyl benzoate; an abietate, such as ethyl abietate or benzyl abietate; dioctyl adipate; isodecyl succinate; dioctyl azelate; an oxalate, such as dibutyl oxalate or dipentyl oxalate; diethyl malonate; amaleate, such as dimethylmaleate, diethyl maleate ordibutyl maleate; tributyl citrate; a sorbate, such as methyl sorbate, ethyl sorbate or butyl sorbate; a sebacate, such as dibutyl sebacate or dioctyl sebacate; an ethylene glycol ester, such as a formic acid monoester or diester, a butyric acid monoester or diester, a lauric acid monoester or diester, a palmitic acid monoester or diester, a stearic acid monoester or diester, or an oleic acid monoester or diester; triacetin; diethyl carbonate; diphenyl carbonate; ethylene carbonate; propylene carbonate; and a borate, such as tributyl borate or tripentyl borate. In an exemplary embodiment, the hydrophobic organic solvent can contain at least tricresyl phosphate, the use of which can contribute to good emulsion stability.

In the case where the electron donor dye precursor to be encapsulated has poor solubility in the hydrophobic organic solvent, a low boiling point solvent having high solubility may additionally be used in combination. Preferred examples of the low boiling point solvent include ethyl acetate, isopropyl acetate, butyl acetate, and methylene chloride.

The electron donor dye precursor compound can be present in any effective amount in a laser-sensitive recording layer of a laser-markable material. Preferably, the electron donor dye precursor can be present in an amount which can result in obtaining a sufficient coloring density, while maintaining the transparency of the laser-markable material. For example, the content of the electron donor dye precursor can be from about 0.1 to about 5.0 g/m², and preferably from about 1.0 to about 4.0 g/m².

During microcapsule formation, water-soluble polymers are added to the aqueous phase of the reaction mixture to form a protective colloid in order to stabilize the emulsified dispersion. The type and addition amount of the water-soluble polymers are selected so that the viscosity of the coating composition of the present invention falls into a range of from about 5 centipoises (cps) to about 30 cps, preferably from about 10 cps to about 25 cps, and most preferably from about 10 cps to about 20 cps. Viscosity is measured using Brookfield Programmable DV-II+ viscometer with S21 small size spindle at 100-200 RPM. Regular RV series spindle may also be used depending on sample quantity.

The water-soluble polymer used to form the protective colloid can be appropriately selected from known anionic polymers, nonionic polymers and amphoteric polymers. The water-soluble polymer preferably has a solubility of 5% or more in water at the temperature at which the emulsification is to be conducted. Specific examples thereof include polyvinyl alcohol and a modified product thereof, polyacrylic amide and a derivative thereof, an ethylene-vinyl acetate copolymer, a styrene-maleic anhydride copolymer, an ethylene-maleic anhydride copolymer, an isobutylene-maleic anhydride copolymer, polyvinyl pyrrolidone, an ethylene-acrylic acid copolymer, a vinyl acetate-acrylic acid copolymer, a cellulose derivative, such as carboxymethyl cellulose and methyl cellulose, casein, gelatin, a starch derivative, gum arabic and sodium alginate. Among these, polyvinyl alcohol, gelatin, and a cellulose derivative are particularly preferred.

The mixing ratio of the oily phase to the aqueous phase can be any ratio, for example, to maintain a suitable viscosity. In an exemplary embodiment, the ratio of the oily phase to the aqueous phase can be from about 0.02 to about 0.6 by weight, and more preferably from about 0.1 to about 0.4 by weight. For example, by use of such ratio, improved productivity of the coating composition as well as optimized stability of the coating composition can be achieved.

In order to further uniformly emulsify and disperse the oily phase and the aqueous phase, a surface-active agent may be added into at least one of either the oily phase or the aqueous phase. The addition amount of the surface-active agent is preferably from about 0.1% to about 5%, and more preferably from about 0.5 to about 2%, based on the weight of the oily phase. In the case that the surface-active agent is added into the aqueous phase, appropriate selection should be given to those anionic or nonionic surface-active agents that do not cause precipitation or aggregation through interactions with the protective colloid. Preferred examples of such surface-active agent include sodium alkylbenzenesulfonate, sodium alkylsulfate, sodium dioctyl sulfosuccinate and a polyalkylene glycol (such as polyoxyethylene nonylphenyl ether).

An emulsion can be formed from the oily phase containing the foregoing components and the aqueous phase containing the protective colloid and the surface-active agent. A device for fine particle emulsification by, for example, high speed agitation or ultrasonic wave dispersion, can be used. For example, a homogenizer such as a Manton Gaulin homogenizer, an ultrasonic wave disperser, a dissolver or a KADY mill can be used. After the emulsification, the emulsion can optionally be heated, for example, to a temperature of from about 30° C. to about 70° C. to accelerate the capsule wall-forming reaction. During the reaction, water can be added to the emulsion which can be effective to decrease the probability of collision of the capsules and/or reduce or prevent aggregation of the capsules. A dispersion for preventing aggregation can also be added during the reaction.

The capsule wall-forming reaction can occur for any suitable duration, for example, as long as several hours, to obtain the objective microcapsules. For example, the capsule wall-forming reaction can result in the formation of carbon dioxide gas, and the cessation of the formation of such gas can mark the completion of the reaction.

Electron Acceptor Developer Dispersion

The electron acceptor developer compound, which reacts with the electron donor dye precursor, may be used singly or in a combination of two or more. The coating composition can be combined with a dispersion containing the electron acceptor developer compound. In an exemplary embodiment, the coating composition can be provided separately from the electron acceptor developer dispersion in order to maintain the stability of the coating composition.

Examples of the electron acceptor compound include an acidic substance, such as a phenol compound, a salicylic acid derivative, an organic acid or a metallic salt thereof, an oxybenzoate, and/or a phenol compound. Specific examples thereof include the compounds described in JP-A-61-291183, the contents of what are incorporated by reference. Among these, a bisphenol compound is preferred from the standpoint of obtaining good coloring characteristics. Compositions of electron acceptor developers are disclosed in U.S. Pat. No. 6,797,318 Example-1 as Developer Emulsion Dispersion, U.S. Pat. No. 5,409,797 Example-1 as Emulsion Dispersion, and U.S. Pat. No. 5,691,757 Example as Color Developer. The contents of such U.S. patents are herein incorporated by reference.

Examples of the bisphenol compound include 2,2-bis(4′-hydroxyphenyl)propane (generic name: bisphenol A), 2,2-bis(4-hydroxyphenyl)pentane, 2,2-bis(4′-hydroxy-3′, 5′-dichlorophenyl)propane, 1,1-bis(4′-hydroxyphenyl)cyclohexane, 2,2-bis(4′-hydroxyphenyl) hexane, 1,1 -bis(4′-hydroxyphenyl)propane, 1,1-bis(4′-hydroxyphenyl)butane, 1,1-bis(4′-hydroxyphenyl)pentane, 1,1-bis(4′-hydroxyphenyl)hexane, 1,1-bis (4′-hydroxyphenyl)heptane, 1,1-bis(4′-hydroxyphenyl) octane, 1,1-bis(4′-hydroxyphenyl)-2-methylpentane, 1,1-bis(4′-hydroxypenyl)-2-ethylhexane, 1,1-bis(4′-hydroxyphenyl)dodecane, 1,4-bis(p-hydroxyphenylcumyl)benzene, 1,3-bis(p -hydroxyphenylcymyl)benzene, bis(p-hydroxyphenyl) sulfone, bis(3-allyl-4-hydroxyphenyl)sulfone and bis(p-hydroxyphenyl)acetic acid benzyl ester. Examples of the salicylic acid derivative include 3,5-di-.alpha.-methylbenzylsalicylic acid, 3,5-di-tert-butylsalicylic acid, 3-.alpha.-.alpha.-dimethylbenzylsalicylic acid and 4-(.beta.-p-methoxyphenoxyethoxy)salicylic acid. Examples of the polyvalent metallic salt thereof include a zinc salt or an aluminum salt. Examples of the oxybenzoate include p-hydroxybenzoic acid benzyl ester, p-hydroxybenzoic acid 2-ethylhexyl ester and .beta.-resorcinic acid 2-phenxyethyl ester. Examples of the phenol compound include p-phenylphenol, 3,5-diphenylphenol, cumylphenol, 4-hydroxy-4′-phenoxydiphenylsulfone.

The electron acceptor compound may be used as a dispersion with water-soluble polymers, organic bases, and other color formation aids or may be used as an emulsion dispersion by dissolution in a high boiling point organic solvent that is only slightly water-soluble or is water-insoluble, mixing with a polymer aqueous solution (aqueous phase) containing a surface-active agent and/or a water-soluble polymer as a protective colloid, followed by emulsification, for example, by a homogenizer. In this case, a low boiling point solvent may be used as a dissolving assistant depending on necessity.

Furthermore, the electron acceptor compound and the organic base may be separately subjected to emulsion dispersion, and also may be dissolved in a high boiling point solvent after mixing, followed by conducting emulsion dispersion. The emulsion dispersion particle diameter is preferably about 1 μm or less. In this case, the high boiling point organic solvent used can be appropriately selected, for example, from the high boiling point oils described in JP-A-2-141279. Among these, the use of an ester compound is preferred from the standpoint of emulsion stability of the emulsion dispersion, and tricresyl phosphate is particularly preferred. The oils may be used as a mixture thereof and as a mixture with other oils.

The water-soluble polymer contained as the protective colloid can be appropriately selected from known anionic polymers, nonionic polymers and amphoteric polymers. The water-soluble polymer preferably has a solubility of about 5% or more in water at a temperature at which the emulsification is to be conducted. Specific examples thereof include polyvinyl alcohol and a modified product thereof, polyacrylic amide and a derivative thereof, an ethylene-vinyl acetate copolymer, a styrene-maleic anhydride copolymer, an ethylene-maleic anhydride copolymer, an isobutylene-maleic anhydride copolymer, polyvinyl pyrrolidone, an ethylene-acrylic acid copolymer, a vinyl acetate-acrylic acid copolymer, a polyurethane, a polyether, a polyether based polyurethane copolymer, a styrene acrylic polymer, a polymer of acrylic or methacrylic acid and their derivative thereof, a polyester or a derivative thereof, a cellulose derivative, such as carboxymethyl cellulose and methyl cellulose, casein, gelatin, a starch derivative, gum arabic and sodium alginate. Among these, polyvinyl alcohol, gelatin, and a cellulose derivative are particularly preferred.

Mixing ratio of the oily phase to the aqueous phase is preferably from 0.02 to 0.6, and more preferably from 0.1 to 0.4 by weight. When the mixing ratio is in the range of from 0.02 to 0.6, a suitable viscosity can be maintained, and thus the production adequacy and stability of the coating composition become excellent.

Mixed Coating Dispersion

In the preparation of a laser-marking material, the coating composition can be mixed with a second developer coating composition containing the electron acceptor developer to prepare a mixed coating dispersion. The mixed coating dispersion can be subsequently coated on a substrate for use as a laser-sensitive recording layer for laser marking. Any suitable ratio of the coating composition and the second developer coating composition can be employed. For example, the ratio can be such that the ratio of total weight of electron donor dye precursors and the total weight of the developers is from about 1:0.5 to about 1:30, preferably from about 1:1 to about 1:10.

The water-soluble polymer used as the protective colloid upon preparation of the microcapsule composition and the water-soluble polymer used as the protective colloid upon preparation of the emulsion dispersion can function as a binder of the laser-sensitive recording layer. The coating composition can also be prepared by adding and mixing a binder separately from the protective colloids. As the additional binder, one with water solubility can be used. Examples thereof include polyvinyl alcohol, hydroxyethyl cellulose, hydroxypropyl cellulose, epichlorohydrin-modified polyamide, an ethylene-maleic anhydride copolymer, a styrene-maleic anhydride copolymer, an isobutylene-maleic salicylic anhydride copolymer, polyacrylic acid, polyacrylic amide, methylol-modified polyacrylamide, a starch derivative, casein and gelatin. To impart water resistance to the binder, a water resisting agent may be added thereto. Additionally or alternatively, an emulsion of a hydrophobic polymer, for example a styrene-butadiene rubber latex, or an acrylic resin emulsion, can be added thereto.

Any suitable coating technique can be used to coat a substrate with the mixed coating dispersion for the formation of the laser-sensitive recording layer. The laser-sensitive recording material can contain methyl cellulose, carboxymethyl cellulose, hydroxyethyl cellulose, a starch compound, gelatin, polyvinyl alcohol, carboxyl-modified polyvinyl alcohol, polyacrylamide, polystyrene or a copolymer thereof, polyester or a copolymer thereof, polyethylene or a copolymer thereof, an epoxy resin, an acrylate series resin or a copolymer thereof, a methacrylate series resin or a copolymer thereof, a polyurethane resin, a polyamide resin or a polyvinyl butyral resin, which can be effective to improve the uniformity of the coat and the strength of the coated film.

Other Additives

The other components in the mark formation layer are not particularly limited and can be appropriately selected depending on necessity, and examples thereof include known melting agents, known UV absorbing agents, and known antioxidants.

A melting agent may be contained in the mark formation layer in an amount effect to improve the laser-responsiveness and/or to accelerate the dye formation reaction. Examples of melting agents include an aromatic ether, a thioether, an ester, an aliphatic amide and an ureide. Specific examples thereof are described in JP-A-58-57989, JP-A-58-87094, JP-A-61-58789, JP-A-62-109681, JP-A-62-132674, JP-A-63-151478, JP-A-63-235961, JP-A-2-184489 and JP-A-2-215585.

Preferred examples of the UV absorbing agent include a benzophenone series, a benzotriazole series, a salicylic acid series, a cyanoacrylate series and an oxalic acid anilide series. Specific examples thereof are described in JP-A-47-10537, JP-A-58-111942, JP-A-58-212844, JP-A-59-19945, JP-A-59-46646, JP-A-59-109055, JP-A-63-53544, JP-B-36-10466, JP-B-42-26187, JP-B-48-30492, JP-B-48-31255, JP-B-48-41572, JP-B-48-54965, JP-B-50-10726, and U.S. Pat. Nos. 2,719,086, 3,707,375, 3,754,919 and 4,220,711.

Preferred examples of the antioxidant include a hindered amine series, a hindered phenol series, an aniline series and a quinoline series. Specific examples thereof are described in JP-A-59-155090, JP-A-60-107383, JP-A-60-107384, JP-A-61-137770, JP-A-61-139481 and JP-A-61-160287.

The coating amount of the other components is preferably from about 0.05 to about 1.0 g/m² , and more preferably from about 0.1 to about 0.4 g/m². The other components may be added either inside the microcapsules or outside the microcapsules, or in the dispersion of the electron acceptor compounds of the composition of the present invention.

Composing the Mark Formation Layer

In order to obtain a coating composition for the mark formation layer of the present invention, the above key components may be mixed uniformly and dispersed within a selected polymer media (binder). In this process, the mix ratio of the coating composition of the present invention is such that the ratio of total weight of electron donor dye precursors and that of the electron acceptor compounds is between from about 1:0.5 to about 1:30, preferably from about 1:1 to about 1:10.

The amount of the electron donor dye precursor in the said mark formation layer is preferably in the range of from about 0.1 to 5.0 g/m². In this range, both a sufficient coloring density can be achieved and the transparency of the laser-sensitive recording layer can also be maintained. More preferably, the amount of the electron donor dye precursor is from about 1.0 to about 4.0 g/m².

In the preparation of the mark formation layer, both the water-soluble polymer used as the protective colloid when preparing for the electron donor dye precursor composition or its microcapsule composition and the water-soluble polymer used as the protective colloid when preparing the electron acceptor dispersion of this invention function as the binder of the mark formation layer.

Adding and mixing another binder separately from the above protective colloids is also possible. Preferably, water soluble polymers are generally used, and examples thereof include polyvinyl alcohol, hydroxyethyl cellulose, hydroxypropyl cellulose, epichlorohydrin-modified polyamide, ethylene-maleic anhydride copolymer, styrene-maleic anhydride copolymer, isobutylene-maleic salicylic anhydride copolymer, polyacrylic amide, methylol-modified polyacrylamide, casein and gelatin.

In order to impart water resistance to the binder, a water resisting agent may be added thereto, and an emulsion of a hydrophobic polymer, specifically a styrene-butadiene rubber latex, a styrene acrylic polymer, a acrylic or methacrylic series polymer or a copolymer and their derivative thereof, a polyester or a copolymer thereof, may be added thereto.

In order to safely and uniformly coat the mark formation layer, and to maintain the strength of the coated film, the mark formation layer of the present invention may further contain methyl cellulose, carboxymethyl cellulose, carboxyl-modified polyvinyl alcohol, polystyrene or a copolymer thereof, polyether, polyurethane resin or a derivative thereof, polyether based polyurethane copolymer, polyethylene or a copolymer thereof, epoxy resin, polyamide resin, polyvinyl butyral resin or starch compounds.

In order to coat a substrate with the mixed coating dispersion to prepare a mark formation layer, a known coating method suitable for aqueous or organic solvent series coating composition is used.

B. Configuration of the Laser Markable Media

Support Layer

The laser markable media can include a support layer which can function as a substrate on which the mark formation layer is coated. In the case that the mark formation layer is coated onto an isolation layer described below, the support layer and the isolation layer can be one in the same. In other cases, the support layer can be underneath the mark formation layer, i.e., further from the direction of the incident laser beam.

In order to obtain a transparent laser-markable material, a transparent support layer with a wavelength range within the visible spectrum can be used. Examples of the transparent support include, but are not limited to, synthetic polymer materials, examples of which include a polyester film, such as polyethyleneterephthalate or polybutyleneterephthalate, a cellulose triacetate film, a polylactide film, a polysulfone film, a polystyrene film, a polyether etherketone film, a polymethylpentene film, a Nylon film, a polyolefin film, such as polypropylene, polyethylene, or BOPP, and polyacrylates, poly(meth)acrylates, urethane acrylates, polycarbonate, polystyrene, and epoxy which can be used singly or in a combination of two or more by lamination.

Top-Coat and Intermediate Layers

The laser-sensitive recording material can include on or above the support, at least one additional layer such as a top coat and/or intermediate layer and an undercoating layer. The top coat and intermediate layers can function as protective coating layers to reduce or prevent mixing of the layers and/or to block a gas (such as oxygen) that can be harmful to the laser-sensitive recording layer. A binder can be used in the top-coat and intermediate layer and is not particularly limited. For example, the binder can include polyvinyl alcohol, gelatin, polyvinyl pyrrolidone, and a cellulose derivative. In order to impart coating suitability, various kinds of surface-active agents can be added. In order to further improve the gas blocking characteristic, inorganic fine particles, such as mica, can be added in an effective amount such as, for example, from about 2 to about 20% by weight, more preferably from about to about 10% by weight, based on the amount of the binder.

Undercoating Layer

An undercoating layer may be provided on or above the support before coating the laser-sensitive recording layer to improve the adhesion of the laser-sensitive recording layer to the support. For example, an acrylate copolymer, polyvinylidene chloride, SBR, or an aqueous polyester can be used. The layer can be of any suitable thickness, for example, from about 0.05 to about 0.5 μm.

The undercoating layer can be hardened by employing a hardening agent. The use of the hardening agent can be effective to reduce or prevent swelling of the undercoating layer by the water content contained in the laser-sensitive recording layer coating composition (which can lead to deterioration of the image recorded on the laser-sensitive recording layer). Examples of the hardening agent include, for example, a dialdehyde compound, e.g., glutaraldehyde or 2,3-dihydroxy-1,4-dioxane, and boric acid. Any effective amount of the hardening agent can be used depending on the material of the undercoating layer, for example, from about 0.2 to about 3.0% by weight corresponding to a desired hardening degree. The hardening agent can be used singly or in a combination of two or more. The undercoating layer is preferably effective to maintain the transparency of the laser-sensitive recording material. For example, the undercoating layer can include a fine particle substance having a refractive index of from about 1.45 to about 1.75.

Isolation Layer

The isolation layer of the laser markable media of the present invention is defined as the medium between the mark formation layer and the laser irradiation source. It can be a supporting sheet on which the mark formation layer is coated, or a coating layer on top of the mark formation layer. The isolation layer and the mark formation layer can be in tight contact through coating or pressure lamination, or in a close proximity through an adhesive layer. In the latter case, the adhesive material should satisfy the same transmittance criteria of the isolation material defined below. The benefits of this isolation medium are: a) block the releasing of undesired chemical vapor resulting from decomposition of the materials in the mark formation layer during laser marking process, b) protect the mark formation layer from mechanical abrasion as well as chemical attack, including harmful gases in the atmosphere, such as O₂, O₃ and SO₂, which tend to accelerate mark fading, background fogging, or yellowing over long period of storage.

Depending on the type of laser selected for the application and the intent for which the laser markable media of the present invention is to be used, the isolation material should be substantially transparent to the specified wavelength of the laser selected. Preferably, the transmittance of the isolation layer is at least about 70% or higher, more preferably about 80% or higher, and most preferably about 90% or higher. Higher transmittance at the specific wavelength of the selected laser ensures minimum attenuation of the delivered laser energy at the mark formation layer, and thus enables a maximum achievable marking speed for at a given laser power. A second benefit of higher transmittance at the specific wavelength of the selected laser is that heat generation within the isolation media, which could induce undesired thermal stress of the material and cause physical distortion, is minimized.

In addition, the isolation layer material should have an on-set pyrolysis temperature that is well above the mark formation temperature. This will ensure that no decomposition of the isolation material occurs during the marking process, and thus no undesired chemical vapor is released. In the case that the electron donor dye precursor is encapsulated, the T_{g} of the microcapsulation material of the present invention should be controlled within a range such that it is well below the on-set pyrolysis temperature of the isolation material. In the case that the electron donor dye precursor and the electron acceptor compound are separated by other dispersing means, either the glass-transition temperature or the melting point of the dispersing or separation media should be chosen to be well below the on-set pyrolysis temperature of the isolation material. In either case, the preferable on-set pyrolysis temperature of the isolation material of the present invention should be at least about 200° C., more preferably about 250° C. and above.

It is not necessary that the isolation material of the invention be transparent in the wavelength range of the visible spectrum (about 400-700 nm), depending on the application requirements. For most applications, a transparent isolation material in the wavelength range of visible spectrum is preferred, which will give a visible mark that is protected by the isolation layer from mechanical abrasion as well as chemical attack.

Suitable isolation materials include polymer films or coating compositions, examples of which include, but are not limited to, a polyolefin film, such as polypropylene, polyethylene, or biaxially oriented polypropylene (BOPP), a polyester film, such as polyethylene terephthalate or polybutylene terephthalate, a cellulose triacetate film, a polylactide film, a polysulfone film, a polystyrene film, a polyether etherketone film, a polymethylpentene film, a nylon film, and coating compositions based on polyurethane resin or polyurethane copolymer, such as urethane-acrylate copolymer and polyether polyurethane copolymer, polyamide resin, epichlorohydrin-modified polyamide, polyacrylates, poly(meth)acrylates or derivatives thereof, core-shell acrylic latex, polyacrylic amide, styrene acrylic polymer polystyrene or a copolymer thereof, such as styrene-maleic anhydride copolymer and styrene-butadiene rubber latex, epoxy resin, ethylene-maleic anhydride copolymer, isobutylene-maleic salicylic anhydride copolymer, polycarbonate, polyester or a copolymer thereof, polyether, polyether based polyethylene or a copolymer thereof, polyvinyl butyral resin, methyl cellulose, carboxymethyl cellulose, and polyvinyl pyrrolidone. For CO₂ laser markable media, polyolefin films and coating formula based on polyurethane or polyurethane copolymer resins are preferred materials for the isolation layer of the present invention. It is understand that not all of the materials in the above list that are suitable for all the emitting wavelengths of the types of lasers listed in the following section describing laser marking equipment.

Other Layers

The laser-markable material of the present invention may further comprise, on the support, other layers, such as a primer layer, an adhesive layer followed with a releasing liner. The primer layer may be provided on the support before coating the mark formation layer, in order to improve the adhesion of the mark formation layer to the support. Depending on the application requirement, an adhesive layer and, if needed, a releasing liner may be coated/laminated on the opposite side of the support from the mark formation layer, to form a laser markable self-adhesive media.

As a primer layer, an acrylate copolymer, polyvinylidene chloride, styrene-butadiene rubber (SBR), or an aqueous polyester can be used, and the thickness of the layer is preferably from 0.05 to 0.5 μm. There are cases where, upon coating the mark formation layer onto the primer layer, the primer layer is swollen by the water content in the composition of the mark formation layer, which could deteriorate the mark quality in the mark formation layer. Therefore it is preferred that the primer layer is hardened with a hardening agent, such as a dialdehyde compound, e.g., glutaraldehyde or 2,3-dihydroxy-1,4-dioxane, and boric acid. These may be used singly or in a combination of two or more.

The addition amount of the hardening agent is appropriately determined depending on the material of the primer layer and selected from the range of from 5 0.2 to 3.0% by weight corresponding to a desired degree of hardening. The layer preferably also includes a fine particle substance having a refractive index of from about 1.45 to about 1.75, from the standpoint that the transparency of the laser-markable media is maintained.

Formation of the Laser Markable Media

The laser-markable media of the present invention can be preferably produced by the process described below, but it is not limited thereto.

The production process of a laser-markable media of the present invention includes the steps of: coating the primer layer (if it is used) onto the support, coating a mark formation layer onto the primer layer (if it is used) on the support; and in the case that the support layer is not the isolation layer, coating an isolation layer on top of the mark formation layer. In the case that the support layer also serves as the isolation layer, the primer layer may optionally be coated on both sides of the support, to facilitate additional printing on the opposite side of the mark formation layer. Depending on necessity, other layers are also formed.

In the production process of the laser-markable media of the present invention, in the case that the support layer is not the isolation layer, the mark formation layer and the isolation layer may be optionally coated simultaneously, and in this case, the coating compositions of the mark formation layer and the isolation layer are subjected to multilayer coating, whereby the mark formation layer and the isolation layer can be simultaneously formed. The technology of multilayer simultaneous coating is particularly suitable, in the case that the mark formation layer is further comprised of separate layers of electron donor dye precursor dispersion and dispersion of electron acceptor compounds.

Alternatively, the laser-markable media of the present invention may be coated sequentially with known coating methods, in the following order: the primer layer, the mark formation layer, and the isolation layer. Examples of these coating methods include, but are not limit to, a blade coating method, an air knife coating method, a gravure coating method, a roll coating method, a spray coating method, a dip coating method and a bar coating method.

Various configurations of the laser-markable media of the present invention are illustrated below in the spirit of this invention, but not limit thereto.

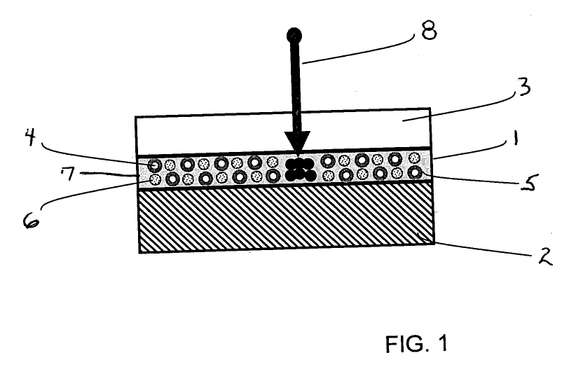

In the embodiment shown in FIG. 1, the mark formation layer 1 is sandwiched between the support 2 and the isolation layer 3, which may be coated or laminated onto the mark formation layer. The mark formation layer comprises the electron donor dye precursor 4 encapsulated by capsule wall and the electron acceptor compound 6, both dispersed in a same polymer medium 7 in close proximity of reaction length, but are prevented from direct contact by the capsule wall and the polymer of the media, when the laser markable material is under ambient temperature below the T_{g} of the polymers. When the energy is delivered into the mark formation layer via a laser beam 8, and the medium temperature is raised beyond the T_{g}, of the capsule wall, the capsule wall expands and opens, which leads to direct contact between the two compounds through migration or diffusion, and the dye precursor is turned into dye. Volatile compounds in the mark formation layer generated during the marking process are kept underneath the isolation layer. The result is that no undesired chemicals are released.

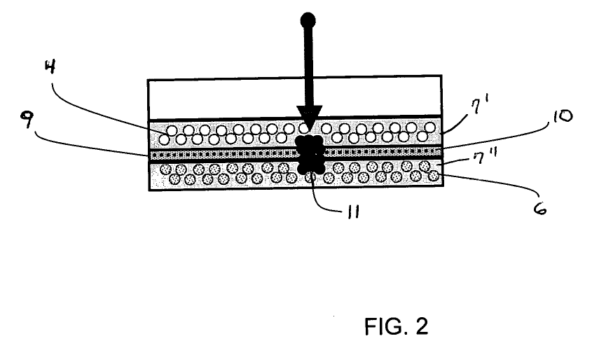

In another embodiment of the present invention shown in FIG. 2, the electron donor dye precursor 4 and electron acceptor compound 6 are dispersed and coated into two distinct layers of polymer medium 7′ and 7″ (which can be the same or different material) isolated by an optional 3^{rd} polymer spacing layer 9, having a glass transition temperature T_{g} similar to that of the capsulation wall above, and additional laser absorption enhancing additive 10 may optionally be dispersed into either this spacing layer alone, or also into the electron acceptor layer.

In this embodiment, when the energy of the incident laser beam is absorbed by the sensitizing agents in exposed areas, the spacing polymer is melted or softened locally, enabling cross-layer diffusion and a reaction between the electron donor dye precursor and the electron acceptor to form marks 11. This arrangement enhances the heat stability of the laser markable media, to prevent undesired interaction between the electron donor dye precursor and electron acceptor, forming fog in unmarked areas.

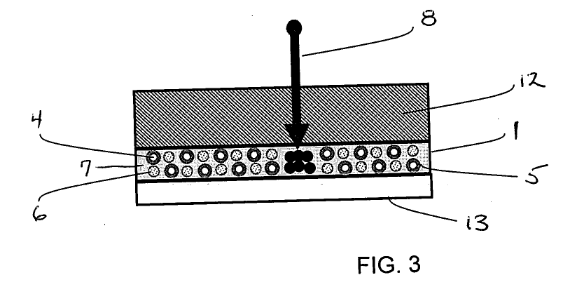

In yet another embodiment shown in FIG. 3, the laser markable media has the same configuration as in FIG. 1. However, the laser beam 8 is irradiated from the support side (based on the definition, this support layer 12 now becomes an isolation layer), which in substantially transparent to the wavelength of the laser beam, but substantially non-transparent in the wavelength range of visible spectrum. On the other hand, the isolation layer 13 is substantially transparent in the wavelength range of visible spectrum, and thus the marks formed in the mark formation layer 1 become visible from the back side. Optionally, an adhesive layer (not shown) may be coated on the other side of the support/isolation layer 12, which, of necessity, must also be substantially transparent to the wavelength of the laser beam.

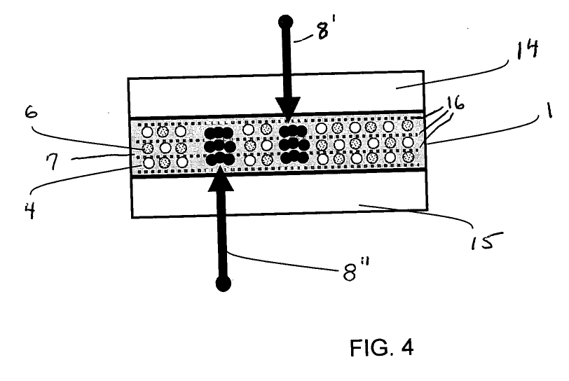

In a variation of the above embodiment of FIG. 4, both isolation layers 14 and 15 are substantially transparent in the wavelength range of visible spectrum. However the isolation layer 14 is also substantially transparent to laser beam 8′ with emission wavelength λ(1), and the isolation layer 15 is also substantially transparent to laser beam 8″ with emission wavelength λ(2), where λ(1) and λ(2) may or may not be the same and the two isolation layers may or may not be significantly transparent to both λ(1) and λ(2), if they are different. The two isolation layers may also be rigid or flexible, or one rigid and one flexible, and/or made from different materials. In FIG. 4, the encapsulated electron donor dye precursor 4 and the electron acceptor compound are located in polymer medium 7 of the mark formation layer 1 which further includes particles of laser absorption additive 16.

In this way, the marks may be formed by marking beams of the same or different frequencies from both sides. The formed marks in this embodiment are therefore resistant to chemical attacks and mechanical abrasions from both sides. In addition, since the marking beam energy is absorbed only in the mark formation layer, which is sandwiched between two isolation layers, thus there is no release of decomposed chemicals or vaporized ingredients into the atmosphere during the marking process.

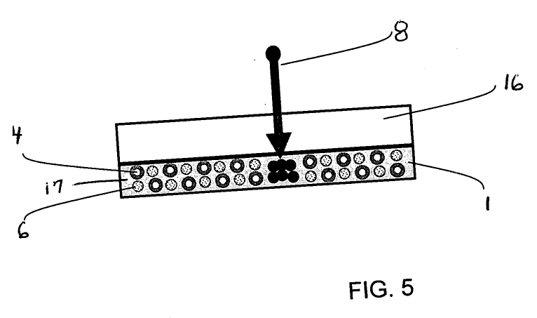

In yet another embodiment shown in FIG. 5, the mark formation layer 1 also serves as an adhesive layer on isolation layer/support 16. Both the encapsulated electron donor dye precursor 4 and the electron acceptor compound 6 are dispersed in an adhesive medium 17. The laser markable media of this embodiment may be adhered onto a product packaging surface, and then marked with a laser beam 8, or the reverse.

Laser Marking Equipment

The laser markable media of the present invention may be marked with a laser such as a CO₂ laser, a YAG laser, a solid laser such as a ruby laser, or a diode laser such as, but not limited to, InGaAsP and GaAs. In an exemplary embodiment, a CO₂ laser can be used as such laser can be effective to provide a higher density mark on the coated material. For example, a 5-20W CW CO₂ laser in the emitting wavelength range of 9.3-10.6 μm can be employed.

A preferred laser marking system is one in which a Galvonometer beam steering technology that allows computer to control the beam with one or more rotating mirrors in X or X/Y-axes is used. Both Vector and Raster scanning schemes may be used depending on the application. Preferably the combination of laser beam quality, f-Θ lens quality, and focal distance will allow the marking spot-size at the focal plane to be below about 300 micron, more preferably to be below about 100 micron.

C. Coating Composition and Laser-Markable Material

According to another aspect, a coating composition is provided which is useful for forming a coating such as a laser-recordable layer on a substrate. The coating can constitute a part of a multi-layered laser-markable material. By employing the coating composition, a laser mark of relatively high quality can be obtained.

The coating composition includes at least one component of a color-forming agent. The color-forming agent can contribute to the generation of a color upon exposure to a laser. For example, the color-forming agent can include at least one component which reacts with at least another component upon exposure to a laser, wherein such reaction results in the generation of a color. The color-forming agent can include an electron donor dye precursor, an electron acceptor developer, or both such components, wherein the reaction between such compounds upon exposure to a laser results in a generation of a color. The coating composition can contain any of the materials discussed above. For example, the electron donor dye precursor can include one or more of the electron dye precursors discussed above. Likewise, the electron acceptor developer can include one or more of the electron acceptor developers discussed above.

In a preferred embodiment, multiple coating compositions can be formed wherein a first coating composition includes the electron donor dye precursor and the second coating composition includes the electron acceptor developer. Such first and second compositions can be maintained separately to improve stability of the compositions, and can be combined and/or mixed together prior to use.

The electron donor dye precursor can include, for example, a triphenylmethane phthalide series compound, a fluorane series compound, a phenothiazine series compound, an indolyl phthalide series compound, a leucoauramine series compound, a rhodamine lactam series compound, a triphenylmethane series compound, a triazene series compound, a spiropyran series compound, a fluorene series compound, a pyridine series compound, a pyradine series compound and a combination thereof. The electron acceptor developer, for reacting with the electron donor dye precursor, can include an acidic substance such as activated bentonite, a metal salt of salicylate, a phenol compound, an organic acid or a metallic salt thereof, an oxybenzoate and a combination thereof.

The composition can include any of the additives discussed above. Additionally or alternatively, the composition can include at least one auxiliary additive such as, for example, a surfactant, an anti-foam agent, a plasticizer, a rheological agent, a biocide, an antistatic agent, a solvent, a photoinitiator for radiation curing or combinations thereof. The auxiliary additive can also include an additive for improving laser-marking performance such as a heat transfer agent, a melting agent, an ultraviolet ray absorbing agent, an antioxidant or combinations thereof.

The heat transfer agent can include a compound which is capable of absorbing C0₂ laser emission energy at 943 cm⁻¹, and converting same to heat. The heat transfer agent can include, for example, mica, fumed silica, fumed alumina, and various inorganic and organic compounds having strong absorption in the wavelength range of 900 cm-⁻¹ to 1000 cm⁻¹. The melting agent can function to improve laser responsiveness. Examples can include an aromatic ether, a thioether, an ester aliphatic amide, a ureide or combinations thereof. The ultraviolet ray absorbing agent can include, for example, a benzophenone series ultraviolet ray absorbing agent, a benzotriazole series ultraviolet ray absorbing agent, a salicylic acid series ultraviolet ray absorbing agent, a cyanoacrylate series ultraviolet ray absorbing agent, an oxalic acid anilide series ultraviolet ray absorbing agent or combinations thereof. The antioxidant can include, for example, a hindered amine series antioxidant, a hindered phenol series antioxidant, an aniline series antioxidant, a quinoline series antioxidant or combinations thereof.

The coating composition also includes a binder which can function as a medium for the color-forming agent. The binder can be selected from the binders discussed above. Preferably, the binder is capable of being processed into a coating or film. In an exemplary embodiment, the binder can include a substituted or unsubstituted polyurethane compound. The substituted or unsubstituted polyurethane compound can include a polyurethane formed from the reaction of an isocyanate with, for example, various organic compounds as discussed in “Polyurethane Handbook,” 2^{nd} Ed., edited by Dr. Günter Oertel, Hanser Publishers, Munich, pp. 17-25 (1994), the contents of which are herein incorporated by reference. Any substituted or unsubstituted polyurethane compound suitable for forming a coating can be used such as, for example, a polyester-derived polyurethane, a polyether-derived polyurethane, a polycarbonate-derived polyurethane, a castor oil-derived polyurethane, or combinations thereof. The substituted or unsubstituted polyurethane compound can be present in an amount of at least about 50% by weight of the total binder content. Preferably, the substituted or unsubstituted polyurethane compound can be present in an amount effective to reduce or substantially eliminate the formation of interference marks. For example, the substituted or unsubstituted polyurethane can yield substantially no interference marks after exposure to laser energy, for example, a CO₂ laser beam. Preferably, the binder is substantially chemically inert with respect to the color-forming agent, and therefore preferably does not interference with the color-forming reaction. The binder can be a water-soluble resin.

In an exemplary embodiment, the polyurethane compound can constitute substantially all of the binder present in the coating composition. Alternatively, additional binder materials can be used in combination with the polyurethane compound. Examples of such additional binder materials include starch and modified derivatives, cellulose and modified derivatives, gelatin, casein, gum arabic, pectin, sodium alginate, silicate resin, polyvinyl alcohol, polyacrylic resin, epoxy, polystyrene, polyester, polyacrylic amide, styrene-acrylic acid copolymer, styrene-butadiene copolymer, ethylene-vinyl acetate copolymer, styrene-maleic anhydride copolymer, ethylene-maleic anhydride copolymer, isobutylene-maleic anhydride copolymer, polyvinyl pyrrolidone, acrylic, ethylene-acrylic acid copolymer, vinyl acetate-acrylic acid copolymer and combinations thereof. An additional binder can be employed, for example, when a special technical property which is imparted by such additional binder, is desired.

The coating composition can contain any suitable amount of binder. In an exemplary embodiment, the binder can be present in an amount of at least about 50% of the total solids weight of the coating composition. In an exemplary embodiment, the binder can be present in an amount from about 5% to about 40%, more preferably from about 10% to about 20%, and most preferably about 15% of the total solid weight in the coating composition.

The coating composition can be a single-part coating composition which contains substantially all of the various components of the coating composition.

Alternatively, multiple coating compositions can be used to provide storage stability prior to use of the compositions, and the binder can be incorporated into any of the multiple coating compositions.

The coating composition can be used to form a coating or film using any suitable technique. For example, the coating or film can be aqueous-based, solvent-based such as an organic-solvent-based, radiation-curable such by as UV radiation, and/or an electron beam-curable. The binder containing the polyurethane compound can be employed as the binder material to reduce or substantially eliminate interference mark effects independent of the specific coating formation method of the coating composition.

Any suitable electron donor dye precursor that is compatible with an electron acceptor developer can be used in the color-forming agent. Compounds represented by general structural Formula 1 can be employed which are capable of being incorporated into the microcapsules in very high concentration and can providing high mark densities:

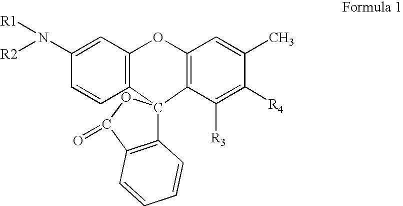

wherein, R₁ and R₂ represent a alkyl group, such as a butyl group, a sec.-butyl group, a tert.-butyl group, a propyl group, an ethyl group, a methyl group, etc.; R₃ represents a hydrogen, or a alkyl group, such as a butyl group, a sec.-butyl group, a tert.-butyl group, a propyl group, a ethyl group, a methyl group, etc.; and R₄ represents an imino-benzene group or a hydrogen. An exemplary compound is shown below as Formula 2:

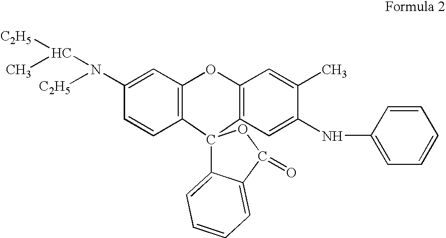

In a preferred embodiment, the solubility of the electron donor dye precursor can be greater than about 10 g/100 g of ethyl acetate, more preferably greater than about 1 5 g/100 g of ethyl acetate, and most preferably greater than about 18 g/100 g of ethyl acetate.

In an exemplary embodiment, the electron donor dye precursor contains greater than about 80% by weight, more preferably greater than about 90%, and most preferably about 100% by weight, of compound(s) represented by structural the above Formula 1.

The color-forming agent can be incorporated in the coating composition using any suitable technique, for example, in the manner discussed above. For example, the color-forming agent can be incorporated by a) dispersing the color-forming agent in solid powder form into the binder medium, b) dissolving the color-forming agent in a solvent and adding the solution of color forming agents to the binder medium, and c) micro-encapsulating the color forming agents and dispersing the encapsulated color forming agents into the binder medium. In an exemplary embodiment, the color forming agents are microencapsulated and dispersed in the binder medium. For example, the color forming agents can be microencapsulated in the manner discussed above.

At least one of the components of the color-forming agent can be present in the coating composition in the form of a microcapsule. For example, the electron donor dye precursor and/or the electron acceptor developer can be microencapsulated. This can depend on, for example, whether it is advisable to protect either or both of such components from being contacted by any other components of the coating composition. In an exemplary embodiment, the dye precursor can be micro-encapsulated and separated from the developer.

An exemplary process for micro-encapsulating a component of the color-forming agent such as an electron donor dye precursor will now be described. For encapsulation, a surface polymerization process can be employed, such that the electron donor dye precursor that becomes a core of the microcapsules is dissolved or dispersed in a hydrophobic organic solvent to prepare an oily phase, which is then mixed with an aqueous phase obtained by dissolving a water-soluble polymer in water. The resulting material is then subjected to emulsification and dispersion by using, for example, an homogenizer, followed by heating, so as to conduct a polymer-forming reaction at the interface of the oily droplets, whereby a microcapsule wall of a polymer substance is formed. Reactants for forming the polymer substance can be added to the interior of the oily droplets and/or the exterior of the oily droplets. Specific examples of the polymer substance include polyurethane, polyurea, polyamide, polyester, polycarbonate, a urea-formaldehyde resin, a melamine resin. Among these, polyurethane, polyurea, polyamide, polyester and polycarbonate are preferred, and polyurethane and polyurea are particularly preferred. For example, in the case where polyurea is used as the microcapsule wall material, the microcapsule wall can be easily formed by reacting a polyisocyanate, such as diisocyanate, triisocyanate, tetraisocyanate or a polyisocyanate prepolymer, with a polyamine, such as diamine, triamine or tetramine, a prepolymer having two or more amino groups, piperazine or a derivative thereof, or a polyol, in the aqueous phase by the interface polymerization process.

A composite wall formed with polyurea and polyamide or a composite wall formed with polyurethane and polyamide can be prepared in such a manner that, for example, a polyisocyanate and a secondary substance for forming the capsule wall through reaction therewith (for example, an acid chloride, a polyamine or a polyol) are mixed with an aqueous solution of a water-soluble polymer (aqueous phase) or an oily medium to be encapsulated (oily phase), and subjected to emulsification and dispersion, followed by heating. The production process of the composite wall formed with polyurea and polyamide is described in detail in JP-A-58-66948.

As the polyisocyanate compound, a compound having an isocyanate group of three or more functional groups is preferred, and a difunctional isocyanate compound may be used in combination therewith. Specific examples thereof include a diisocyanate, such as xylene diisocyanate or a hydrogenated product thereof, hexamethylene diisocyanate or a hydrogenated product thereof, tolylene diisocyanate or a hydrogenated product thereof and isophorone diisocyanate, as the main component; a dimer or a trimer thereof (burette or isocyanaurate); a compound having polyfunctionality as an adduct product of a polyol, such as trimethylolpropane, and a difunctional isocyanate, such as xylylene diisocyanate; a compound of an adduct product of a polyol, such as trimethylolpropane, and a difunctional isocyanate, such as xylylene diisocyanate, having a polymer compound, such as polyether having an active hydrogen, such as polyoxyethylene oxide, introduced therein; and a formalin condensation product of benzeneisocyanate.

The compounds described in JP-A-62-212190, JP-A-4-26189, JP-A-5-317694 and Japanese Patent Application No. 8-268721 can be preferably used. Specific examples of the polyol and/or the polyamine added to the aqueous phase and/or the oily phase as one constitutional component of the microcapsule wall through the reaction with the polyisocyanate include propylene glycol, glycerin, trimethylolpropane, triethanolamine, sorbitol and hexamethylenediamine. In the case where a polyol is added, a polyurethane wall is formed. An exemplary polyisocyanate, polyol, reaction catalyst and polyamine for forming a the microcapsules are described in “Polyurethane Handbook” written by Keiji Iwata, and published by Nikkan Kogyo Shimbun, Ltd. (1987) and “Polyurethane Handbook,” 2^{nd} Ed., edited by Dr. Güinter Oertel, Hanser Publishers, Munich (1994).

In an exemplary embodiment, at least about 90% of the total volume of the dye precursor particles is present in microcapsules having an average particle diameter of from about 0.3 μm to about 12 μm, preferably from about 0.2 μm and about 5 μm, and most preferably from about 0.2 μm and about 2 μm. Preferably, the microcapsules have an average particle diameter of from about 0.3 to about 12 μm, preferably from about 0.2 μm and about 5 μm, and most preferably from about 0.2 μm and about 2 μm. The thickness of the microcapsule wall can be from about about 0.01 μm and about 0.3 μm. Particle size of the microcapsules in the suspension can be measured by diluting the suspension into aqueous solution and using laser scattering method based on Mie-scattering theory to measure the particle size and distribution. Typical equipment used for such measurement are Horiba's LA series, Beckman Coulter's LS series or Malvern Instruments' Mastersizer series.

The microencapsulation reaction can also be controlled so that the microcapsule wall has a glass transition temperature, T_{g}, of from about 150° C. to about 190° C., preferably from about 160° C. to about 180° C., and most preferably from about 165° C. to about 175° C. The T_{g} of the microcapsule wall can be measured by using conventional differential thermal analysis methods, such as DSC (Differential Scanning Calorimeters) or DDSC (Dynamic DSC), which measures specific heat (Cₚ) change over different temperature ranges. Both a microcapsule-containing suspension and a blank suspension are placed in the sample trays before measurement. Typical equipment used for such measurements are Perkin Elmer Diamond DSC, Sapphire DSC, HyperDSC™, or TA Instruments Q-series.

Various reaction conditions of the microcapsule preparation process can be controlled and adjusted in order to obtain microcapsules having the preferred characteristics. These conditions cam include, for example, emulsification process of the electron donor dye precursor, addition rates and amounts of the polyisocyanate and polyamine to form the microcapsule wall, as well as mixing and reaction temperature, time, and agitation. In the reaction, the reaction rate can be increased, for example, by either maintaining a high reaction temperature or by adding an appropriate polymerization catalyst.

The microcapsule wall may further contain, depending on the specific application, a metal-containing dye, a charge adjusting agent, such as nigrosin, and/or other additive substances. These additives may be contained in the capsule wall during wall formation or at other times during the microencapsulation process. In order to adjust the charging property of the surface of the capsule wall, a monomer, such as a vinyl monomer, can be graft-polymerized depending on necessity.

Furthermore, in order to make a microcapsule wall having excellent substance permeability at low temperature and having the quality of high coloring properties, a plasticizer can be used that is suitable for the polymer that is used as the wall material. The plasticizer can have a melting point of about 50 degrees C. or more, and more preferably about 120 degrees C. or more. Among plasticizers, those in a solid state at ordinary temperature can be preferably employed. For example, in the case where the wall material comprises polyurea or polyurethane, as a plasticizer a hydroxyl compound, a carbamate compound, an aromatic alkoxy compound, an organic sulfoneamide compound, an aliphatic amide compound, an arylamide compound or combinations thereof can be used.

As a hydrophobic organic solvent used for forming the core of the microcapsule by dissolving the electron donor dye precursor compound upon preparing the oily phase, an organic solvent having a boiling point of from about 100 to about 300 degrees C. can be used. Specific examples thereof include an ester compound, dimethylnaphthalene, diethylnaphthalene, diisopropylnaphthalene, dimethylbiphenyl, diisopropyldiphenyl, diisobutylbiphenyl, 1-methyl-1-dimethylphenyl-2-phenylmethane, 1-ethyl-1-dimethylphenyl-1-phenylmethane, 1-propyl-1-dimethylphenyl-1-phenylmethane, triarylmethane (such as tritoluylmethane or toluyldiphenylmethane), a terphenyl compound (such as terphenyl), an alkyl compound, an alkylated diphenyl ether (such as propyldiphenyl ether), hydrogenated terphenyl (such as hexahydroterphenyl) and diphenylterphenyl. Among these, an ester compound can be preferably used from the standpoint of emulsification stability of the emulsion dispersion. Examples of the ester compound include a phosphate, such as triphenyl phosphate, tricresyl phosphate, butyl phosphate, octyl phosphate or cresylphenyl phosphate; a phthalate, such as dibutyl phthalate, 2-ethylhexyl phthalate, ethyl phthalate, octyl phthalate or butylbenzyl phthalate; dioctyl tetrahydrophthalate; a benzoate, such as ethyl benzoate, propyl benzoate, butyl benzoate, isopentyl benzoate or benzyl benzoate; an abietate, such as ethyl abietate or benzyl abietate; dioctyl adipate; isodecyl succinate; dioctyl azelate; an oxalate, such as dibutyl oxalate or dipentyl oxalate; diethyl malonate; amaleate, such as dimethylmaleate, diethyl maleate ordibutyl maleate; tributyl citrate; a sorbate, such as methyl sorbate, ethyl sorbate or butyl sorbate; a sebacate, such as dibutyl sebacate or dioctyl sebacate; an ethylene glycol ester, such as a formic acid monoester or diester, a butyric acid monoester or diester, a lauric acid monoester or diester, a palmitic acid monoester or diester, a stearic acid monoester or diester, or an oleic acid monoester or diester; triacetin; diethyl carbonate; diphenyl carbonate; ethylene carbonate; propylene carbonate; and a borate, such as tributyl borate or tripentyl borate.

The hydrophobic organic solvent can be used alone or in combinations of two or more. Among these, tricresyl phosphate can be preferably used, either singly or as a mixture with other solvents since it provides high emulsion stability. In the case where the electron donor dye precursor to be encapsulated has poor solubility in the hydrophobic organic solvent, a low boiling point solvent having high solubility can additionally be used in combination. Examples of the low boiling point solvent include ethyl acetate, isopropyl acetate, butyl acetate and methylene chloride.

In an exemplary embodiment where the electron donor dye precursor compound is used in the laser-sensitive recording layer of the laser-sensitive recording material, the content of the electron donor dye precursor is preferably from about 0.1 to about 5.0 g/m², and more preferably from about 1.0 to about 4.0 g/m². While not wishing to be bound by any particular theory, it is believed that when the content of the electron donor dye precursor is in the range of from about 0.1 to 5.0 g/m², a sufficient coloring density can be obtained, and when the content is 5.0 g/m² or less, a sufficient coloring density can be achieved while the transparency of the laser-sensitive recording layer can also be maintained.

During microcapsule formation, water-soluble resins can be added to the aqueous phase of the reaction mixture as a binder in order to stabilize the emulsified dispersion and formed microcapsules. The type and addition amount of the water-soluble resins can be selected so that the viscosity of the coating composition has a viscosity of from about 5 centipoise (cP) to about 30 cP, preferably from about 10 cP to about 25 cP, and most preferably from about 10 cP to about 20 cP. Viscosity can be measured using Brookfield Programmable DV-II+ viscometer with small sample adapter plus a S21 spindle at 100-200 RPM. Regular RV series spindle can also be used depending on sample quantity.

In order to further uniformly emulsify and disperse the oily phase and the aqueous phase, a surfactant can be added to at least one of the oily phase and the aqueous phase. Any suitable surfactant for emulsification can be used. The addition mount of the surfactant can be from about 0.1% to about 5%, more preferably from about 0.5 to about 2%, based on the weight of the oily phase. As the surfactant contained in the aqueous phase, one that does not cause precipitation or aggregation through an action with the binder can be used by appropriately selecting from anionic and nonionic surfactants. Preferred examples of the surface-active agent include sodium alkylbenzenesulfonate, sodium alkylsulfate, sodium dioctyl sulfosuccinate and a polyalkylene glycol (such as polyoxyethylene nonylphenyl ether).

The emulsification can be conducted by subjecting the oily phase containing the foregoing components and the aqueous phase containing the binder and the surfactant to a device generally used for fine particle emulsification, such as high speed agitation or ultrasonic wave dispersion by using a known emulsifying apparatus, such as a homogenizer, Manton Gaulin, an ultrasonic wave disperser, a dissolver or a KADY mill. After emulsification, the emulsion can be heated to a temperature of from to 70° C. for accelerating the capsule wall-forming reaction. During the reaction, water can be added to the emulsion to decrease the probability of collision of the capsules or that sufficient agitation is conducted to prevent aggregation of the capsules.

A dispersion containing the polyurethane compound may further be added during the reaction for reducing or substantially preventing aggregation. Formation of a carbon dioxide gas can be observed with progress of the reaction, and termination of the formation can be determined as completion of the capsule wall-forming reaction. In general, the reaction can be conducted for several hours to obtain the objective microcapsules.

Examples of the electron acceptor compound, which is capable of reacting with the electron donor dye precursor, include an acidic substance, such as activated bentonite, metal salt of salicylate, phenol compound, organic acid or its metallic salt, oxybenzoate or combinations thereof.

Specific examples thereof include a bisphenol compound, such as 2,2-bis(4′-hydroxyphenyl)propane (generic name: bisphenol A), 2,2-bis(4-hydroxyphenyl)pentane, 2,2-bis(4′-hydroxy-3′, 5′-dichlorophenyl)propane, 1,1-bis(4′-hydroxyphenyl)cyclohexane, 2,2-bis(4′-hydroxyphenyl) hexane, 1,1 -bis(4′-hydroxyphenyl)propane, 1,1-bis(4′-hydroxyphenyl)butane, 1,1-bis(4′-hydroxyphenyl)pentane, 1,1-bis(4′-hydroxyphenyl)hexane, 1,1-bis (4′-hydroxyphenyl)heptane, 1,1-bis(4′-hydroxyphenyl) octane, 1,1 -bis(4′-hydroxyphenyl)-2-methylpentane, 1,1-bis(4′-hydroxypenyl)-2-ethylhexane, 1,1-bis(4′-hydroxyphenyl)dodecane, 1,4-bis(p-hydroxyphenylcumyl)benzene, 1,3-bis(p -hydroxyphenylcymyl)benzene, bis(p-hydroxyphenyl) sulfone, bis(3-allyl-4-hydroxyphenyl)sulfone and bis(p-hydroxyphenyl)acetic acid benzyl ester; a salicylic acid derivative, such as 3,5-di-.alpha.-methylbenzylsalicylic acid, 3,5-di-tert -butylsalicylic acid, 3-.alpha.-.alpha.-dimethylbenzylsalicylic acid and 4-(.beta.-p -methoxyphenoxyethoxy)salicylic acid; a polyvalent metallic salt thereof (in particular, a zinc salt and an aluminum salt are preferred); an oxybenzoate, such as p-hydroxybenzoic acid benzyl ester, p-hydroxybenzoic acid 2-ethylhexyl ester and beta.-resorcinic acid 2-phenxyethyl ester; and a phenol compound, such as p-phenylphenol, 3,5-diphenylphenol, cumylphenol, 4-hydroxy-4′-phenoxydiphenylsulfone. Among these, the metal salts of salicylate can be preferred employed, for example, zinc salicylate. For example, it is possible to achieve good coloring characteristics by using such developer. Additional electron acceptor developers that can be used are disclosed in U.S. Pat. Nos. 6,797,318, 5,409,797 and U.S. Pat. No. 5,691,757, the contents of which are incorporated by reference herein. The electron acceptor compounds may be used singly or in a combination of two or more.

The electron acceptor compound may be used, for example, as a solid dispersion prepared in a sand mill with water-soluble polymers, organic bases, and other color formation aids or may be used as an emulsion dispersion by dissolution in a high boiling point organic solvent that is only slightly water-soluble or is water-insoluble, mixing with waterborne polyurethane and its modified derivatives as the binder (aqueous phase), followed by emulsification, for example, by a homogenizer. In this case, a low boiling point solvent can be used as a dissolving assistant depending on necessity.

Furthermore, the electron acceptor compound and the organic base may be separately subjected to emulsion dispersion, and also may be dissolved in a high boiling point solvent after mixing, followed by subjecting to emulsion dispersion. The emulsion dispersion particle diameter can be about 1 μm or less. In this case, the high boiling point organic solvent used can be appropriately selected, for example, from the high boiling point oils described in JP-A-2-141279. Among these, the use of an ester compound is preferred from the standpoint of emulsion stability of the emulsion dispersion, and tricresyl phosphate is particularly preferred. The oils can be used as a mixture thereof and as a mixture with other oils.

In an exemplary coating composition, the binder can be present from an amount of about 5% to about 50%, preferably from about 10% to about 30%, more preferably about 15% of total solid weight of the coating composition containing the electron acceptor developer.

A coating composition containing the electron acceptor developer and a second coating composition containing the electron donor dye precursor can be mixed together to prepare a mixed coating dispersion which is subsequently coated on a substrate for use as a laser-sensitive recording layer for laser marking. In this process, the two coating compositions can be mixed in any suitable ratio, for example, such that the ratio of total weight of electron donor dye precursor(s) and the total weight of the developer(s) is from about 1:0.5 to about 1:30, preferably from about 1:1 to about 1:0.

In order to safely and uniformly coat the laser-sensitive recording layer coating composition and to maintain the strength of the coated film, besides the two coating compositions described above, extra amount of binder resins and auxiliary additives can be used. In addition, to coat a substrate with the mixed costing dispersion to prepare a laser-sensitive recording layer, a known coating method applied to an aqueous or organic solvent series coating composition can be used for coating the laser-sensitive recording layer coating composition on a substrate.

In an exemplary embodiment, a laser-markable material is provided which includes a coating comprising a substituted or unsubstituted polyurethane compound; and a laser-markable layer. The coating can be in contact with the laser-markable layer.

The laser-markable material can include additional layers such as a protective layer, an intermediate layer, an undercoating layer (a primer layer), a light reflection preventing layer, and the like. The protective layer can be the uppermost layer of the material, and can be arranged above and/or in contact with the laser-sensitive recording layer. The function of the protective layer is to provide protection for the laser-sensitive recording layer against physical damage such as rubbing, moisture attack, to strengthen the resistance against instant heat impact, etc. The intermediate layer can be applied on the laser-sensitive recording layer. The function of this layer is to reduce or prevent intermixing of the layers and also for blocking a gas (such as oxygen) that may be harmful in order to preserve an image after formation. The undercoating layer, light reflection preventing layer and other functional layers such as an adhesion layer can be applied onto the substrate before coating the laser-sensitive recording layer.

Since the protective layer is of interest to provide protection for the color forming layer in a laser markable material, a protective coating composition can also be provided according to an exemplary embodiment. For example, the protective coating composition not only can provide the demanded protection as described above, but also be effective to reduce or eliminate the formation of interference marks that affect the mark quality of a laser marked material. The binder quantity for the protective layers can be, for example, about 50% of total solid weight in the coating composition. The percentage of binder quantity can vary in from about 10% to about 80% according to different application, more preferably from about 30% to about 60% by weight.

Using substantially only a polyurethane compound as the binder for the additional layers is preferred for a good mark quality. A combination between polyurethane and other type of resins, such as acrylic, epoxy, cellulose, etc., can be a selected when a special technical property is demanded for a laser markable material. For example, the amount of polyurethane and its modified derivatives is preferably not less than 50% of the total binder quantity in a coating composition to reduce or avoid intensifying the interference mark effect.

The additional layer(s) can include auxiliary additives such as regular coating additives, such as surfactants, anti-foam agents, plasticizers, rheological agents, biocides, antistatic agents, solvents, water, photoinitiator for radiation curing, hardening agents, etc. For example, the additional layer(s) can include a fine particle substance having a refractive index of from about 1.45 to about 1.75 from the standpoint that the transparency of the laser markable material is maintained.

By employing the above-described laser-markable material, methods and systems, various advantages can be realized such as, for example, low equipment and running cost; high-quality and rapid marking with fine line letters and simple patterns (vector scan); flexible resolution adjustment, tone control and pattern change (raster scan); relatively large and flexible marking area; and/or small-lot (short-run) high throughput production with variable information marking. Use of the above-described laser-markable material, methods and systems can enable high-quality, rapid laser marking on a wide variety of substrates, including materials that do not typically respond or have a weak response to a laser beam (such as a relatively low-powered, low-cost CO₂ laser), or materials that can be easily damaged by the laser irradiation without forming quality marks. For example, use of the laser-markable materials can enable marking of substrates having a wide range of material and geometries such as hard and soft plastics and polymers for engineering materials or commercial goods (PET, BOPP, HDPE, PMMA, poly-carbonate and Nylons), or paper, cardboard, fiberglass, glass, metals, etc.

The laser-markable material, methods and systems described above can be used in any application in which a material is laser-marked. Examples of such applications include, but are not limited to: package or product direct labeling, coding and marking for identification, tracking or consumer warning purpose (batch or serial numbers, expiration dates); pressure-sensitive self-adhesive films or labels for individual or packaged products; transportation shipping labels (both direct and adhesive labels); addressing for mass-mailing and franking; ID tag marking, such as apparel tagging and animal ID tagging; paper ticket printing; ID card printing; security applications, such as smart card, anti-counterfeiting, or tamper-evident seal and label applications.

### EXAMPLES

Examples of the various embodiments of the present invention are given below, but the invention should not be construed as being limited thereto.

### Example 1

[Preparation of Liquid Dispersion (A) Containing an Encapsulated Electron Donor Dye Precursor]

13.3 g of electron donor dye precursor represented by Formula (1), where R1 is C₄H₉ and R2 is C₂H₅, and 0.47 g of an UV light absorbing agent (trade name: Tinuvin P, Ciba Geigy Corp.) were added in 20 g of ethyl acetate and dissolved by heating up to 70° C., and then cooled down to 45° C. 12.6 g of diisocyanate compound (trade name: Takenate D-140N, Mitsui Takeda Chemical Co., Ltd.) was added into the ethyl acetate solution. The above ethyl acetate solution was then added into 53 g of 6%w/w polyvinyl alcohol aqueous solution (trade name: Kuraray Poval MP-217C, Kuraray Co., Ltd.) and emulsified with a homogenizer for 5 minutes. Finally, an amine solution of 90 g water and 0.5 g of tetraethylenepentamine were gradually added into the above mixture while agitating at 60° C. for 4 hours to conduct an encapsulation reaction.

After the reaction was completed, the particle size distribution of the encapsulated electron donor dye precursor particles was measured with a Beckman Coulter's LS-100Q particle size analyzer, the viscosity of the liquid coating composition was measured with a Brookfield Programmable DV-II+ viscometer with S21 small size spindle at 100-200 RPM, and the T_{g} of the microcapsule wall was measured by using a Perkin Elmer's Diamond DSC with a blank suspension without microcapsule as reference. The following results were obtained: viscosity of the liquid dispersion =18 cps, wherein 99% (volume) of the microcapsules have particle-size between 0.2-2 μm, and the microcapsule wall T_{g} =156° C.

[Preparation of Liquid Dispersion (B) Containing an Electron Acceptor Compound]

4.2 g of an UV light absorbing agent (trade name: Tinuvin 328, Ciba Geigy), 1.0 g of tricresylphosphate, and 36.4 g of an electron acceptor compound (compound 301 of U.S. Pat. No. 6,797,318) were added in 16.0 g of ethyl acetate, and dissolved by heating up to 70° C. This ethyl acetate solution was added into the following aqueous solution and dispersed with a homogenizer for 5 minutes.

Aqueous Solution for Emulsified Dispersion (B)

| | | |
|---|---|---|
| Water | 68.4 | g |
| 15% w/w Poly-vinylalcohol (trade name: Poval PVA205, Kuraray Co., Ltd.) | 19.8 | g |
| 8% w/w Poly-vinylalcohol (trade name: Poval PVA217, Kuraray Co., Ltd.) | 55.7 | g |
| Surfactant A, 2% solution C₁₂H₁₅SO₃Na | 11.2 | g |
| Surfactant B, 2% solution C₉H₁₉(C₆H₄)O(CH₂)₄SO₃Na | 11.2 | g |
| [Preparation of a mixed coating composition for coating the mark formation layer] | | |
| The above dispersion (A) and dispersion (B) were mixed as follows. | | |
| Dispersion (A) | 8.9 | g |
| Dispersion (B) | 33 | g |

[Coating the Mark Formation Layer Onto a Support]

The above coating composition was coated onto a 75 μm thick A4 size transparent PET film at ˜10 μm coating thickness with a bar coater, followed with about 3 minutes drying at 60° C. The PET film had been preliminarily coated with SBR latex and gelatin mixture as primer.

[Complete the Laser Markable Media and Mark the Media with a CO₂ Laser Marker]

The above sheet was divided into three equal portions. One portion (invention) was pressure laminated with a 50 μm transparent polyethylene (PE) film on top of the coated mark formation layer, another portion (invention) was further coated with a clear core-shell type acrylic latex dispersion (trade name: Rhoplex Multilobe 200) on top of the coated mark formation layer, and the last portion remains without further treatment (comparison).

A Domino S100 10W CO₂ laser marker with an emitting wavelength of 10.3 μm and 80 mm f-Θ lens was used. The marking condition was set at “Mark-Speed” =8000 bits/ms and “Laser on CO₂”=200 μs. After turning on the laser marker, sharp and high contrast marks were generated on all three samples. However, the comparison sample without an isolation layer showed smoke release during the marking process, while the two samples of the invention did not. Further, when using a microscope to observe the surface of the samples where marks formed, the comparison sample without an isolation layer shows clear damage on the surface of the coating, while the two samples of the invention did not. Rubbing tests also show that the comparative sample had much more severe surface damage on the media.

### Example 2

For reference, the following Table 1 lists electron donor dye precursor compounds, and includes the corresponding solubility in ethyl acetate, which are used in the following examples.

TABLE 1

| | | Solubility in |
|---|---|---|
| | | ethyl acetate |
| Dye | | (g/100 |
| Precursor | Structure | grams) |
| D-1 | Formula (1), when R1 is C₄H₉ and R2 is C₂H₅ | 18 |
| D-2 | Formula (4) | 5 |
| D-3 | Formula (5) | 4 |
| D-4 | Formula (2) | 60 |
| D-5 | Formula (3) | 20 |
| D-6 | Formula (6) | 5 |

| | |
|---|---|
| | Formula (4) |
| 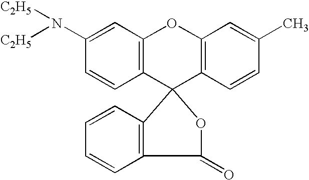 | |
| | Formula (5) |
| 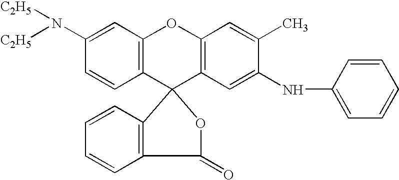 | |
| | Formula (6) |
| 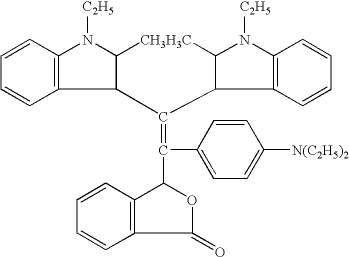 | |

### Example 2-1

[Preparation of Liquid Coating Composition Containing an Encapsulated Electron Donor Dye Precursor]

Sample 1 (Comparison)

13.3 g of electron donor dye precursor D-1 and 0.47 g of an UV light absorbing agent (trade name: Tinuvin P, Ciba Geigy Corp.) were added in 20 g of ethyl acetate and dissolved by heating up to 70° C., and then cooled down to 45° C. 14.1 g of capsule wall material W-1 (trade name: Takenate D-127N, Mitsui Takeda Chemical Co., Ltd.) and 2.5 g of capsule wall material W-2 (trade name: Takenate D-110N, Mitsui Takeda Chemical Co., Ltd.) were added to the ethyl acetate solution.

The above ethyl acetate solution was added to 53 g of 6% w/w polyvinyl alcohol aqueous solution B-1 (trade name: Kurary Poval MP-217C, Kuraray Co., Ltd.) and emulsified with a homogenizer for minutes.

90 g of water and 0.75 g of tetraethylenepentamine were added and mixed with a stirrer at 60° C. for 4 hours for encapsulation reaction.

After the reaction was completed, the particle size distribution of the encapsulated electron donor dye precursor particles and the viscosity of the liquid coating composition were measured with Beckman Coulter's LS-100Q particle size analyzer and Brookfield Programmable DV-II+ viscometer with S21 small size spindle at 100-200 RPM.

The T_{g} of the microcapsule wall was measured by using Perkin Elmer's Diamond DSC, Sapphire DSC, HyperDSC™, or TA Instruments' Q-series. A blank suspension without microcapsule was prepared under the same conditions as a reference sample. Both the microcapsule containing suspension and the blank suspension were placed in the sample trays before measurement.

Sample 2 (Comparison)

Sample 2 was prepared in the same way as described in the Sample 1 preparation except that the capsule wall materials W-1 and W-2 were replaced with 12.6 g of W-3 (trade name: Takenate D-140N, Mitsui Takeda Chemical Co., Ltd.).

Sample 3 (Comparison)

Sample 3 was prepared in the same way as described in the Sample 1 preparation except that the capsule wall materials W-1 and W-2 were replaced with 12.6 g of W-3 (trade name: Takenate D-140N, Mitsui Takeda Chemical Co., Ltd.), the addition amount of the 6% w/w poly-vinylalcohol aqueous solution B-1 was changed to 40 g, and the addition amount of the water for the emulsification was changed to 103 g.

Sample 4 (Comparison)

Sample 4 was prepared in the same way as described in the Sample 1 preparation except that the capsule wall materials W-1 and W-2 were replaced with 12.6 g of W-3 (trade name: D-140N, Mitsui Takeda Chemical Co., Ltd) and 2.3g of W-4 (trade name: Bamoc D750, Dai Nippon Ink Co., Ltd.), the addition amount of the 6% w/w poly-vinylalcohol aqueous solution B-1 was changed to 33 g, and g of 8% w/w poly-vinylalcohol aqueous solution B-2 (trade name: Kuraray Poval PVA217, Kurary Co., Ltd.) was added.

Sample 5 (Invention)

Sample 5 was prepared in the same way as described in the Sample 1 preparation except that the capsule wall materials W-1 and W-2 were replaced with 12.6 g of W-3 (trade name: Takenate D-140N, Mitsui Takeda Chemical Co., Ltd.) and the addition amount of the tetraethylenepentamine was changed to 0.5 g.

Sample 6 (Invention)

Sample 6 was prepared in the same way as described in the Sample 1 preparation except that the capsule wall materials W-1 and W-2 were replaced with 12.6 g of W-3 (trade name: Takenate D-140N, Mitsui Takeda Chemical Co., Ltd.).

Sample 7 (Invention)

Sample 7 was prepared in the same way as described in the Sample 1 preparation except that the capsule wall material W-1 and W-2 were replaced with 12.6g of W-3 (trade name: Takenate D-140N, Mitsui Takeda Chemical Co., Ltd.), the addition amount of the 6% w/w poly-vinyl alcohol aqueous solution B-1 was changed to 45 g, the addition amount of the water for the emulsification was changed to 98 g, and the addition amount of the tetraethylenepentamine was changed to 2.0 g.

Sample 8 (Invention)

Sample 8 was prepared in the same way as described in the Sample 1 preparation except that the amount of the electron donor dye precursor of formula (1), where RI is C₄H₉ and R2 is C₂H₅, was reduced to 8.3 g, 5.0 g of electron donor dye precursor D-6 was added, the capsule wall materials W-1 and W-2 were replaced with 12.6 g of W-3 (trade name: Takenate D-140N, Mitsui Takeda Chemical Co., Ltd.), the addition amount of the 6% w/w poly-vinyl alcohol aqueous solution B-1 was changed to 40 g, and 13 g of 8% w/w poly-vinyl alcohol aqueous solution B-2 (trade name: Kuraray Poval PVA217, Kurary Co., Ltd.) was added.

T_{g}, particle size distributions, and viscosities of the above Sample 1 to Sample 8 are listed in Table-2, below.

Storage Stability Test on the Samples

Samples 1 to 8 were placed in polyethylene bottles and then stored in an oven, where the temperature was changed between 20° C. and 40° C. every 12 hours, for 4 weeks, and then the appearance of each sample was observed. The results are listed in Table-2.

TABLE 2

| | Sample No. | | | | | | | |
|---|---|---|---|---|---|---|---|---|
| | 1 | 2 | 3 | 4 | 5 | 6 | 7 | 8 |
| | (Comp.) | (Comp.) | (Comp.) | (Comp.) | (Inv.) | (Inv.) | (Inv.) | (Inv.) |
| Tg of capsule wall | 145° C. | 171° C. | 175° C. | 193° C | 156° C. | 175° C. | 185° C. | 175° C. |
| % of particle | 99% | 82% | 99% | 99% | 99% | 99% | 99% | 99% |
| size 0.2-2 μm | | | | | | | | |
| Viscosity | 14 cp | 13 cp | 4 cp | 37 cp | 18 cp | 13 cp | 9 cp | 26 cp |
| Changes in | none | Phase | Slight | none | none | none | none | none |
| appearance after | | separation; | phase | | | | | |
| 4 weeks (if any) | | capsule | separation | | | | | |
| | | precipitation | | | | | | |

Performance Evaluation of Coated Film Samples

The following coated film samples were prepared in the following way using the above Samples 1 to 8 from both before and after the 4 week storage test and an emulsified developer dispersion.

[Preparation of Emulsified Developer Dispersion]

4.2 g of an UV light absorbing agent (trade name: Tinuvin 328, Ciba Geigy), 1.0 g of tricresylphosphate, and 36.4 g of a developer (compound 301 of U.S. Pat. No. 6,797,318) were added in 16.0 g of ethyl acetate, and dissolved by heating up to 70° C. This ethyl acetate solution was added in the below described aqueous solution and dispersed with a homogenizer for 5 minutes.

Aqueous Solution for Emulsified Developer Dispersion

| | |
|---|---|
| Water | 68.4 g |
| 15% w/w Poly-vinylalcohol (trade name: Poval PVA205, | 19.8 g |
| Kurary Co., Ltd.) | |
| 8% w/w Poly-vinylalcohol (trade name: Poval PVA217, | 55.7 g |
| Kurary Co., Ltd.) | |
| Surfactant A, 2% solution C₁₂H₁₅SO₃Na | 11.2 g |
| Surfactant B, 2% solution C₉H₁₉(C₆H₄)O(CH₂)₄SO₃Na | 11.2 g |

[Preparation of a Mixture for Coating]

Each of the above described Samples 1 to 8 and the emulsified developer dispersion were mixed by mixing 8.9 g of each sample with 33 g of the emulsified developer dispersion.

[Coating of a Mixture on a PET Film]

Each of the above mixture was coated at 1 5ml/m² on a film of A4 size and 75 μm thickness PET which was preliminarily coated with SBR lutex and gelatin, and the following laser marking was applied after drying.

[Laser Marking Test]

A matrix exposure consisting of 70 of the same mark, the letter “M”, was applied onto each of the coated film samples, using a Domino S-100 CO₂ laser marker with a f=80 mm lens, which provides 35 mm×35 mm marking field and a spot size of from about 250 to about 280 μm. The design of the test marking matrix is such that each row consists of 7 characters, with increasing laser power output from 26.5% to 100% (5.2W→19.6W from left to right), and 20% power increment between neighboring characters, and each column consists of 10 characters, with increasing marking speed from 1300 bits/mS to 9500 bits/mS (from bottom to top), and 20% speed increment between neighboring characters. The sensitivity and latitude of each coated film sample to laser exposure was evaluated by counting the letters which were perfectly marked and distinctly readable. The results from the laser marking test are shown in Table 3.

In addition, a storage stability test of coated film samples was conducted under 80° C. and relative humidity 70% for a week. Fog increases after the storage were measured with X-Rite Densitometer in visual and transparent mode (reflection and transmission mode). The coated film samples for this test were prepared from Samples 1 to 8 before the 4 week storage. The results from this test are also shown in the Table 3.

TABLE 3

| | Sample No. | | | | | | | |
|---|---|---|---|---|---|---|---|---|
| | 1 | 2 | 3 | 4 | 5 | 6 | 7 | 8 |
| | Comp. | Comp. | Comp. | Comp. | Invent | Invent | Invent | Invent |
| Counted Letters | 41 | 22 | 41 | 28 | 47 | 51 | 48 | 41 |
| before storage | | | | | | | | |
| Counted letters | 36 | 4 | 12 | 22 | 42 | 47 | 44 | 38 |
| after storage | | | | | | | | |
| Fog Increase | 0.28 | 0.06 | 0.11 | 0.04 | 0.09 | 0.03 | 0.03 | 0.05 |

As shown in Tables 2 and 3, the liquid coating composition formed in accordance with the present invention is physically and chemically very stable and can be stored for a relatively long time. The coating composition also has a high sensitivity and wide latitude to laser exposure and a less increase in fog by aging.

### Example 2-2

Coated film Samples 9 to 12 were prepared in the same manner as coated film Sample 6 except for changes to the quantity and type of electron donor dye precursor compounds, as summarized in Table 4, below.

TABLE 4
Quantity (grams) added of each type of
electron donor dye precursor compound

| | Sample No. | | | | |
|---|---|---|---|---|---|
| | D-1 | D-2 | D-3 | D-4 | D-5 |
| 9 | 6.7 | 3.3 | 3.3 | 0 | 0 |
| 10 | 6.7 | 1.0 | 1.0 | 4.6 | 0 |
| 11 | 6.7 | 1.9 | 5.0 | 0 | 0 |
| 12 | 6.7 | 1.0 | 1.0 | 2.3 | 2.3 |

Each of the above samples 9 to 12 was subjected to the same laser marking test methods as described in Example 1, above. The sensitivity and latitude of each coated film sample to laser exposure was evaluated by counting the letters which were perfectly marked and distinctly readable. The results from the laser marking test are shown in Table 5.

TABLE 5

| | 9 | 10 | 11 | 12 |
|---|---|---|---|---|
| Sample No. | (Inv.) | (Inv.) | (Inv.) | (Inv.) |
| Counted Letters | 40 | 48 | 41 | 47 |
| % of electron dye donor precursor | 50 | 85 | 50 | 85 |
| compound with solubility > 15 g/100 g | | | | |
| ethyl acetate | | | | |

### Example 3

### Example 3-1:

Laser Exposure of Various Binder Materials

Several different types of binder materials were exposed to a CO₂ laser to determine the effects thereof. The experimental procedure included the following: a) coating the sample resin solution on a 1″×4″ glass slide using a K Control Coater (RK Print Coat Instruments, Ltd.), wherein No. 8 coating bar is used to produce a film thickness of 100 micrometers when wet; b) drying the coated resin solution overnight under ambient condition; c) scanning the coated resins with a Domino S 100 laser maker (Domino Amjet, Inc.) under equal laser intensity; d) observing interference mark (such as micro bubble, foaming effect) formation under Leica GZ6 microscope, and ranking the amount of interference markings (foaming effect) formed from 1 to 10; e) rescanning the sample having the maximum foaming effect and the sample having the minimum foaming effect with varying laser dosages by adjusting the scan speed, and observing the differences in foaming effect in relation to the rate of laser irradiation. The experimental results are shown in the following Table 3-1-1:

TABLE 3-1-1

| | | | | Degree of |
|---|---|---|---|---|
| | | | | Foam |
| Sample | | Main | | (at 2000 |
| No. | Sample | Composition | Supplier | bits/ms) |
| 1 | NeoRez | Urethane/ | NeoResins, Inc. | 5 |
| | R9009 | Acrylic | (Wilmington, | |
| | | Copolymer | MA) | |
| 2 | Zinpol 330 | Acrylic | Noveon, Inc. | 7 |
| | | | (Cleveland, | |
| | | | OH) | |
| 3 | WaterPoxy | Epoxy | Cognis Co. | 4 |
| | 1455 | | (Cincinnati, | |
| | | | OH) | |
| 4 | Joncryl 89 | Styrened | Johnson | 10 |
| | | Acrylic | Polymer | |
| | | | (Sturtevant, WI) | |
| 5 | Hybridur | Urethane/ | Air Products & | 4 |
| | 570 | acrylic hybrid | Chemicals | |
| | | polymer | (Allentown, | |
| | | | PA) | |
| 6 | Macekote | Polyether-based | Mace Company | 1 |
| | 9525 | polyurethane | (Dudley, MA) | |

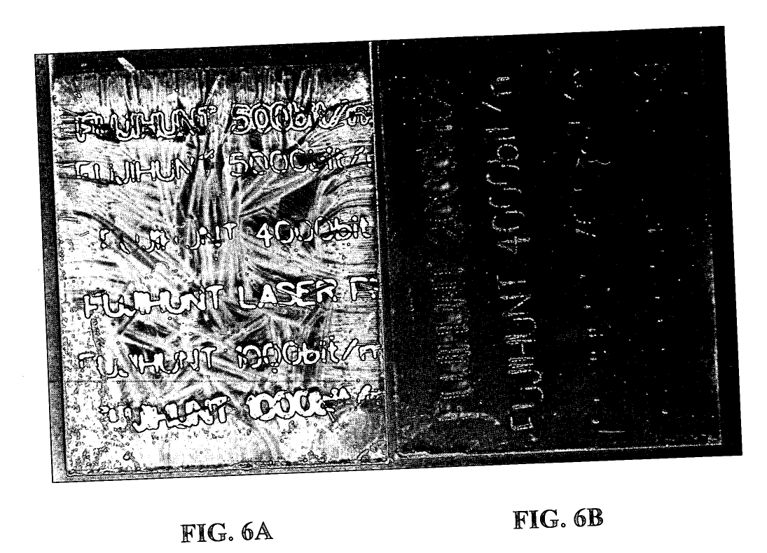

As can be seen from Table 3-1-1, Joncryl 89 yielded the highest degree of foaming effect,and Macekote 9525 yielded the least degree of foaming effect at the scan rate of 2000 bits/ms (bits per millisecond). The two were rescanned (according step (e) discussed above) woth varying laser scanning rates, and the results are shown in FIG. 6, wherein A corresponds to Joncryl 89 and B corresponds to Macekote 99525.

The various scan rates employed to generate the marks shown in FIG. 6 are summarized in Table 3-1-2:

TABLE 3-1-2
Scan Rates for Each Line in FIG. 1, (bits/ms)

| Joncryl 89 | Macekote 9525 |
|---|---|
| (A, from top to bottom | (B, from left to right of |
| of the slide) | the slide) |
| 500 | 2000 |
| 5000 | 4000 |
| 4000 | 7000 |
| 2000 | 10000 |
| 10000 | |
| 1000 | |

As clearly shown in FIG. 6, Joncryl 89 (A) and Macekote 9525 (B) produced very different responses when scanned at comparable rates. Joncryl 89 foamed conspicuously while Macekote 9525 had only minimal foaming effect. Especially at the scan rate of 10,000 bits/ms, Macekote 9525 had comparatively little response to the laser beam. The experimental results show that Macekote 9525 (a polyether-based polyurethane) provided superior results in comparison with the other rested resins in terms of generating less interference marks under CO₂ laser exposure.

### Example 3-2:

Laser Exposure of Various Inventive and Comparative Binders

The effects of laser exposure of five inventive polyurethane dispersions (Sample Nos. 3 to 7) were compared to those of polyvinyl alcohol and styrened acrylate (comparative Sample Nos. 1 and 2, respectively). A blank glass slide was used as a reference.

TABLE 3-2-1

| Sample | | | | |
|---|---|---|---|---|
| No. | Sample | Main Composition | Supplier | Comments |
| 1 | Polyvinyl | Polyvinyl alcohol | ALDRICH | comparative |
| | alcohol | 87-89% hydrolyzed | | |
| 2 | Joncryl 89 | Styrened Acrylic | Johnson | comparative |
| | | | Polymer | |
| 3 | Macekote | Polyether-based | Mace | Inventive |
| | 9525 | polyurethane | Company | |
| 4 | Alberdingk | Polyether-based | Alberdingk | Inventive |
| | U 400N | polyurethane | Boley, Inc. | |
| 5 | Alberdingk | Polyester-based | Alberdingk | Inventive |
| | U 2101VP | polyurethane | Boley, Inc. | |
| 6 | Alberdingk | Polycarbonate-based | Alberdingk | Inventive |
| | U 9152VP | polyurethane | Boley, Inc. | |
| 7 | Alberdingk | Castor oil-based | Alberdingk | Inventive |
| | CUR 21 | polyurethane | Boley, Inc. | |

The experimental procedure included the following: a) coating the tested sample solution on a 1″×4″ glass slide using a K Control Coater (RK Print Coat Instruments, Ltd.), wherein No. 7 coating bar was used to produce a film thickness of 80 micrometers when wet; b) drying the coated sample solution overnight under ambient condition; c) exposing the coated samples with a Domino S100 laser maker (Domino Amjet, Inc.) under a matrix exposure. The matrix exposure consisted of 70 of the same mark, the letter “M”, and was applied onto each of the coated samples, using a Domino S-100 CO₂ laser marker with a f=80 mm lens, which provides 35 mm ×35 mm marking field and a spot size of from about 250 to about 280 μm. The design of the test marking matrix was such that each row consisted of 7 characters, with increasing laser power output from 26.5% to 100% (5.2W→-19.6W from left to right), and 20% power increment between neighboring characters, and each column consisted of characters, with increasing marking speed from 1300 bits/msec to 9500 bits/msec (from bottom to top), and 20% speed increment between neighboring characters.

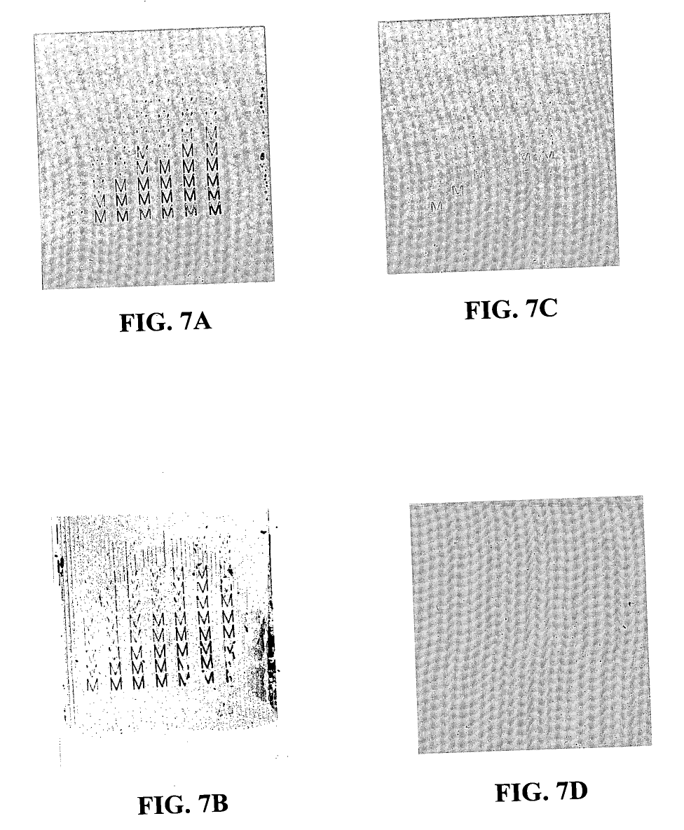

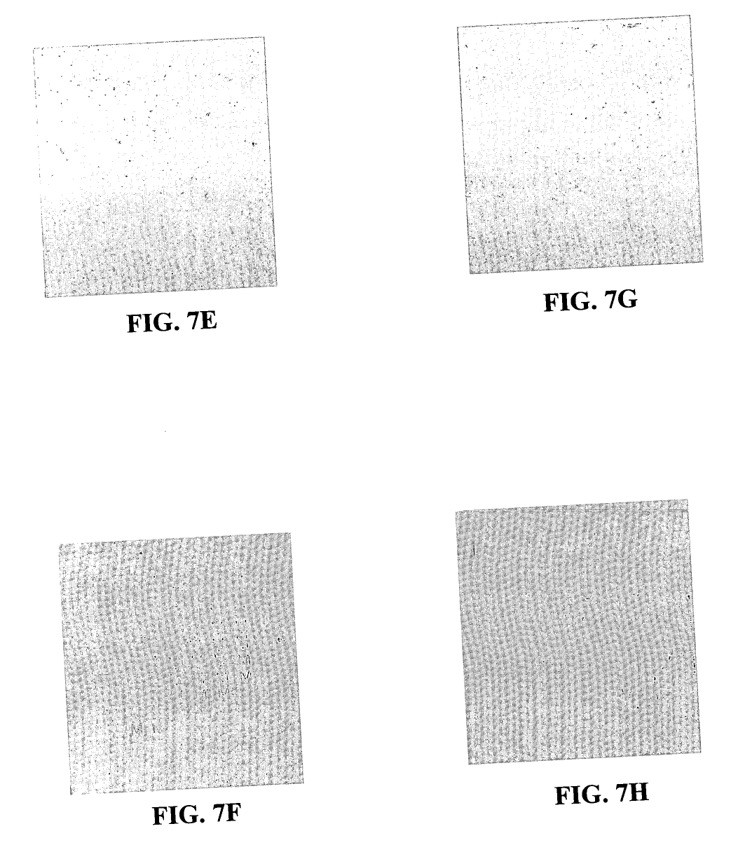

A picture was taken for the CO₂ laser matrix-exposed samples on a black background. The number of white “M” letters and degree of whiteness of the letter were compared to determine the sample that had minimum response to CO₂ laser energy. The photographs are shown in FIGS. 7A to 7H, which correspond to Polyvinyl Alcohol, Joncryl 89, MaceKote 9525, Alberdingk U400N, Alberdingk U 2101VP, Alberdingk U 9152VP, Alberdingk CUR 21 and a blank glass slide, respectively. The experimental results show that polyurethane and its derivatives including polyether-based polyurethane, polyester-based polyurethane, polycarbonate-based polyurethane and castor oil-based polyurethane can provide improved performance in comparison with polyvinyl alcohol and styrened acrylate, in reducing interference marking caused by CO₂ laser exposure.

### Example 3-3:

Preparation and Laser Exposure of a Coating Composition Formed from Two Parts

In this experiment, various polyurethane compounds were used as a binder in making two parts of a coating composition, in which Part A was a coating composition containing the micro-encapsulated dye precursor, and Part B was a coating composition containing the electron acceptor-type developer. Polyvinvl alcohol was used in this experiment as a reference binder to compare the experimental results.

1) Preparation of Part A—Coating Composition containing Micro-Encapsulated Dye Precursor

13.3 g of electron donor-type dye precursor (PSD- 184, Nippon Soda) and 0.47 g of a UV light absorbing agent (Tinuvin P, Ciba Geigy Corp.) were added in 20 g of ethyl acetate and dissolved by heating up to 70° C., and then cooled down to 45° C. 12.6 g of capsule wall material (D-140N, Mitsui Takeda Chemical Co., Ltd.) was added into the ethyl acetate solution. The above ethyl acetate solution was added in 53 g of 6%w/w polyvinyl alcohol aqueous solution (Kurary Poval MP-217C, Kuraray Co., Ltd.) and emulsified with a homogenizer for minutes. 80 g of water and 0.75 g of tetraethylenepentamine were added and mixed with a stirrer at 60° C. for 4 hours for encapsulation reaction. Part A was completed, and the coating composition is referred to as A_{ref}.

The particle size distribution of the encapsulated electron donor-type dye precursor particles and the viscosity of the liquid coating composition were measured with Beckman Coulter's LS-100Q particle size analyzer and Brookfield Programmable DV-II+viscometer with S21 small size spindle at 100-200 RPM. The T_{g} of the microcapsule wall was measured by using Perkin Elmer's Diamond DSC, Sapphire DSC, HyperDSC™, or TA Instruments' Q-series. A blank suspension without microcapsule was prepared under the same conditions as a reference sample. Both the microcapsule-containing suspension and the blank suspension were placed in the sample trays before measurement.

Other test solutions (A₁, A₂, A₃, and A₄) were made in the same manner as A_{ref}, wherein the quantity of binder sample was adjusted if necessary to equal that of A_{ref} based on its solid content. Table 3-3-1 lists the various Part A coating compositions which were formed:

TABLE 3-3-1

| Test No. | Binder Material | Comments |
|---|---|---|
| A_{Ref} | Kurary Poval MP-217C | Comparative |
| | (Polyvinyl alcohol) | |
| A₁ | Alberdingk U400N | Inventive |
| A₂ | Alberdingk U650 | Inventive |
| A₃ | Alberdingk U9152VP | Inventive |
| A₄ | Alberdingk CUR 21 | Inventive |

2) Preparation of Part B—Coating Composition Containing the Electron Acceptor-Type Developer

4.2g of a UV light absorbing agent (Tinuvin 328, Ciba Geigy), 1.0 g of tricresylphosphate, and 36.4 g of developer (RO54, Sanko Chemicals) were added in 160. Og of ethyl acetate, and dissolved by heating up to 70° C. The ethyl acetate solution was added to the aqueous solution described in Table 3-3-2 and dispersed with a homogenizer for 5 minutes.

TABLE 3-3-2
Aqueous solution for emulsified developer dispersion

| | |
|---|---|
| Water, | 68.4 g |
| 15% w/w Poly-vinylalcohol (Poval PVA205, Kurary Co., Ltd.), | 19.8 g |
| 8% w/w Poly-vinylalcohol (Poval PVA217, Kurary Co., Ltd.), | 55.7 g |
| Surfactant A, | 11.2 g |
| Surfactant B, | 11.2 g |

Part B was completed at this step, and the coating composition is hereinafter referred to as B_{ref}.

Other sample Part B solutions (B₁, B₂, B₃, and B₄) were made in the same manner as Bref, wherein the quantity used for each sample was adjusted if necessary to equal that of B_{ref}, based on its solid content. Table 3-3-3 lists the sample Part B coating compositions which were formed:

TABLE 3-3-3

| Test No. | Binder Material | Comments |
|---|---|---|
| B_{Ref} | Kurary Poval PVA205 | Comparative |
| | Kurary Poval PVA217 | |
| B₁ | Alberdingk U400N | Inventive |
| B₂ | Alberdingk U650 | Inventive |
| B₃ | Alberdingk U9152VP | Inventive |
| B₄ | Alberdingk CUR 21 | Inventive |

3) Preparation of Coating Pot Solutions by Mixing Part A and Part B

Each of the Part A samples was mixed with its corresponding Part B sample Aᵢ+Bᵢ). The mixing ratio was as set forth below:

| | | |
|---|---|---|
| Part A | 5.04 | g |
| Part B | 19.13 | g |
| Deionized Water | 6.40 | g |
| To make coating pot solution | 30.57 | g |

The coating pot solutions formed from Aᵢ+Bᵢ are referred to hereafter as Tᵢ.

4) Coat the Coating Pot Solution on PET Film

Each of the above mixtures was coated in an amount of 15 ml/m² on a film of A4 size and 75 μm thickness PET, which was preliminarily coated with SBR lutex and gelatin, and the following laser marking was conducted after drying. Coating was conducted using a K Control Coater (RK Print Coat Instruments, Ltd.), and a No. 3 coating bar was used to form a film thickness of 24 micrometers when wet.

5) Laser Exposure

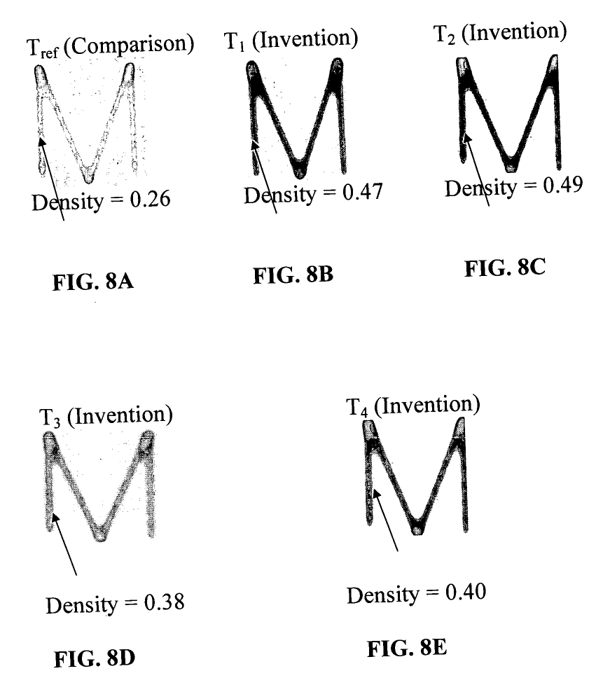

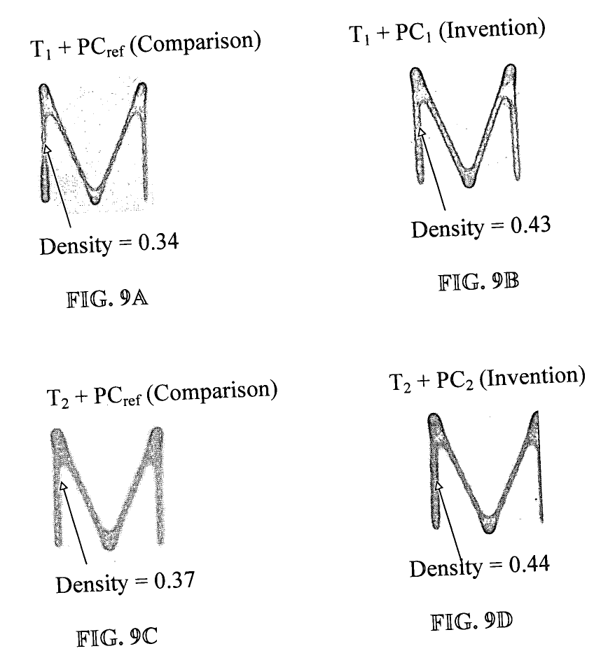

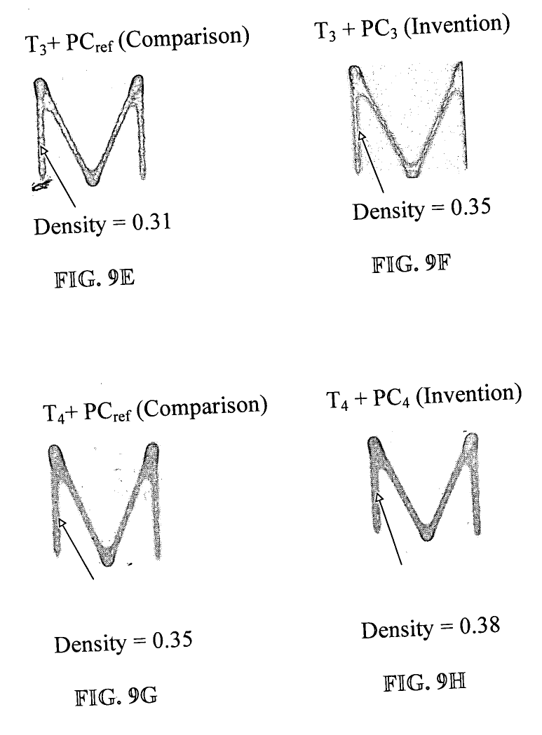

The coated samples were exposed by a Domino S 100 laser maker (Domino Amjet, Inc.) under a matrix exposure as described in Example 3-2. The mark density of a specific letter “M” that best represents the marking results after receiving a fixed quantity of laser energy in the matrix was observed, and the experimental results are shown in FIGS. 8A to 8E. A letter “M” in the matrix, representing a specific laser exposure condition (Laser on time=53 μs, and Mark speed=2030 bits/ms) was selected to compare the mark density of each tested sample. The density in the same position of the letter was measured. As can be seen from the Figures, employing a substituted or unsubstituted polyurethane compound as a binder in the coating composition was effective to improve the mark density of a laser markable material.

### Example 3-4:

Laser Exposure of a Binder-Containing Protective Layer

Various polyurethane compounds were used as a binder to form sample protective layer coating compositions. Polyvinyl alcohol was used as a reference binder to compare the experimental results.

1) Preparation of the Protective Coat Composition

The compounds listed in Table 3-4-1 were added one by one, wherein each successive ingredient was added after the previous one fully dissolved or dispersed.

TABLE 3-4-1

| | | | Amount, |
|---|---|---|---|
| | Chemical | Supplier | g |
| 1 | Deionized Water | | 73.24 |
| 2 | Surfactant A, 72% w/w | | 1.34 |
| 3 | Surfactant B, 50% w/w | | 1.44 |
| 4 | Polyvinyl Alcohol | Kurary Co., Ltd. | 5.60 |
| | (PVA124C) | | |
| 5 | Acetic Acid, 2% w/w | | 7.50 |
| 6 | Deionized Water | | 82.08 |
| 7 | Surfactant C | DAI-ICHI KOGYO | 0.32 |
| | (PLYSURFA217E) | SEIYAKU | |
| 8 | Surfactant D | SEIMI CHEMICAL | 1.70 |
| | (Sarfron S131S) | | |

The protective coating composition was completed at this step. The coating composition is referred to hereinafter as PC_{ref}.

Other sample solutions (PC₁, PC₂, PC₃, and PC₄) were prepared in the same manner as for PC_{ref}, wherein the amount of binder used was adjusted if necessary to equal that of PC_{ref} based on its solid content. Table 3-4-2 lists the various sample protective layer coating compositions which were formed:

TABLE 3-4-2

| Test No. | Binder Material | Notes |
|---|---|---|
| PC_{Ref} | Kurary Poval PVA124C | Comparative |
| PC₁ | Alberdingk U400N | Inventive |
| PC₂ | Alberdingk U650 | Inventive |
| PC₃ | Alberdingk U9152VP | Inventive |
| PC₄ | Alberdingk CUR 21 | Inventive |

2) Coating the Protective Layer Coating Composition on a Color Forming Layer

Each of the coated films (T₁, T₂, T₃ and T₄) in Example 3-3 was coated with the protective layer coating composition prepared above. Tᵢ was coated with PCᵢ and PC_{ref} to observe any differences in laser mark quality. For instance, T₁, was coated with PC₁, and PC_{ref}, and so on. Coating was conducted using a K Control Coater (RK Print Coat Instruments, Ltd.), wherein a No. 3 coating bar was used to give the film thickness of 24 micrometer when wet.

3) Laser Exposure

The coated samples were exposed by a Domino S 100 laser maker (Domino Amjet, Inc.) under a matrix exposure described in Example 3-2. The mark density of a specific letter “M” that best represents the marking result after receiving a fixed quantity of laser energy in the matrix was observed, and the experimental results are shown in FIGS. 4A to 4H. A letter “M” in the matrix, representing a specific laser exposure condition (Laser on time=53 μs, and Mark speed=2030 bits/ms), was selected to compare the mark density of each tested sample. The density in the same position of the letter was measured. As can be seen from the figures, replacing polyvinyl alcohol with the polyurethane compounds as a binder in a protective layer showed improvements in retaining the mark density of markings formed in the recording layer of a laser-markable material.

We claim:

1. A media that can generate a human-readable or machine-readable mark under the irradiation of a focused beam of electromagnetic wave of specific wavelength and intensity, said media comprising:
(a) a mark formation layer comprising at least one electron donor dye precursor and at least one electron acceptor compound which reacts with said electron donor dye precursor upon contact at an elevated temperature to form a colored dye, wherein said electron donor dye precursor is separated from said electron acceptor compound in the mark formation layer by either encapsulating said dye precursor within a polymer having a glass transition temperature, T_{g}, of from about 120° C. to about 190° C., or by dispersing said electron donor dye precursor and said electron acceptor compound into two distinct sub-layers isolated by a third polymer spacing sub-layer having a glass transition temperature, T_{g}, or a melting point, Tₘ, of from about 120° C. to about 190° C., and wherein at least about 90% of the total volume of said electron donor dye precursor, when encapsulated, has a diameter from about 0.2 μm to about 5 μm; and
(b) an isolation layer which is substantially transparent at the wavelength of the focused beam irradiation source, and which has an on-set pyrolysis temperature of at least 200° C.

2. The media of claim 1 wherein said mark formation layer forms readable marks upon exposure to a focused beam irradiation source having a wavelength in the range from about 230 nm to about 11 μm.

3. The media of claim 1 wherein said mark formation layer forms readable marks upon exposure to a focused beam irradiation source having a wavelength in the range from about 900 nm to about 11 μm.

4. The media of claim 1 wherein said isolation layer has an on-set pyrolysis temperature of at least 250° C.

5. The media of claim 1 wherein said isolation layer has a transmittance level of at least 70% at the emitting wavelength of the focused beam of electromagnetic wave.

6. The media of claim 1 wherein said isolation layer has a transmittance level of at least 90% at the emitting wavelength of the focused beam of electromagnetic wave.

7. The media of claim 1 wherein said isolation layer has a transmittance level of at least 97% at the emitting wavelength of the focused beam of electromagnetic wave.

8. The media of claim 1 wherein said mark formation layer and said isolation layer are contacted through an adhesive layer which does not have substantial absorption at the emitting wavelength of the focused beam of electromagnetic wave.

9. The media of claim 1 wherein said electron donor dye precursor has the following structure: 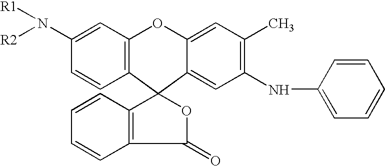
where, R1is —CH(CH₃)C₂H₅ and R2 is —C₂H₅.

10. The media of claim 1 wherein said electron donor dye precursor has the following structure:

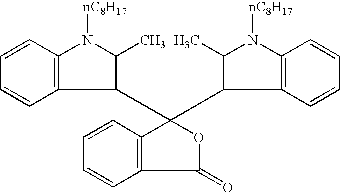

11. The media of claim 1 wherein said electron donor dye precursor has the following structure:

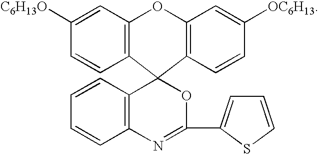

12. The media of claim 1 wherein at least about 90% (by volume) of said electron donor dye precursor, when encapsulated, have a particle diameter from about 0.2 μm to about 2 μm.

13. The media of claim 1 wherein said electron acceptor compound in said mark formation layer is in the form of particles wherein at least about 90% (by volume) of the particles have a diameter from about 0.1 μm to about 3 μm.

14. The media of claim 1 wherein said electron acceptor compound in said mark formation layer is in the form of particles wherein at least about 90% (by volume) of the particles have a diameter from about 0.1 μm to below 2 μm.

15. The media of claim 1 wherein the ratio of the total weight of said electron donor dye precursor to the total weight of said electron acceptor compound in said mark formation layer is from about 1:0.5 to about 1:30.

16. The media of claim 1 wherein the ratio of the total weight of said electron donor dye precursor to the total weight of said electron acceptor compound in said mark formation layer is from about 1:1 to about 1:10.

17. The media of claim 1 wherein said electron donor dye precursor is encapsulated in a polymer material having a glass transition temperature T_{g} of between 150° C. and 190° C. and comprising at least one polyurethane.

18. The media of claim 1 wherein said electron donor dye precursor and said electron acceptor compound are separated by a polymer spacing sub-layer having a glass transition temperature, T_{g}, or a melting point, Tₘ, of from about 150° C. to about 190° C.

19. The media of claim 1 wherein said electron donor dye precursor is encapsulated, and said electron acceptor compound and said encapsulated electron donor dye precursor are dispersed in an adhesive medium.

20. The media of claim 1 wherein said mark formation layer further comprises at least one absorption enhancing additive that absorbs at the wavelength of the focused beam.

21. The media of claim 20 wherein said at least one absorption enhancing additive does not have substantial absorption in the wavelength range of the visible spectrum and wherein when the absorption enhancing additive is in the form of solid particles, the solid are dispersed in said mark formation layer wherein 90% (by volume) of said solid particles have diameters below 5 μm.

22. The media of claim 21 wherein when the absorption enhancing additive is in the form of solid particles 90% (by volume) of said solid particles have diameters below 0.5 μm.

23. The media of claim 1 further comprising a support on which said mark formation layer is coated wherein said mark formation layer is between said support and said isolation layer.

24. The media of claim 23 wherein at least one of said isolation layer and said support is substantially transparent in the wavelength range of visible spectrum.

25. A method of generating a human-readable or machine-readable mark comprising exposing a media to irradiation of a focused beam of electromagnetic wave of specific wavelength and intensity, said media comprising:
(a) a mark formation layer comprising at least one electron donor dye precursor and at least one electron acceptor compound wherein said electron donor dye precursor is separated from said electron acceptor compound in the mark formation layer by either encapsulating said dye precursor within a polymer having a glass transition temperature, T_{g}, of from about 120° C. to about 190° C., or by dispersing said electron donor dye precursor and said electron acceptor compound into two distinct sub-layers isolated by a third polymer spacing sub-layer having a glass transition temperature, T_{g}, or a melting point, Tₘ, of from about 120° C. to about 190° C., and wherein at least about 90% of the total volume of said electron donor dye precursor, when encapsulated, has a diameter from about 0.2 μm to about 5 μm; and
b) an isolation layer which is substantially transparent at the wavelength of the focused beam irradiation source, and which has an on-set pyrolysis temperature of at least 200° C.,
wherein the media is exposed to said focused beam through the isolation layer and said focused beam causes formation of a colored dye that provides the human-readable or machine-readable mark in the mark formation layer.

26. A coating composition for forming a laser-markable material, comprising electron donor dye precursor particles encapsulated with a polymer having a glass transition temperature, T_{g}, of from about 150° C. to about 190° C., wherein at least about 90% of the total volume of the dye precursor particles have a diameter from about 0.2 μm to about 5 μm.

27. The coating composition of claim 26, wherein at least 70% w/w of the total amount of the electron donor dye precursor has a solubility of higher than about 10 g/100 g of ethyl acetate.

28. The coating composition of claim 26, wherein the composition has a viscosity of from about 5 cp to about 30 cp.

29. The coating composition of claim 26, wherein the polymer having a T_{g} of from about 150° C. to about 190° C. comprises a polyurethane.

30. The coating composition of claim 26, wherein the laser-markable material is capable of being marked with a CO₂ laser beam having a wavelength of about 10.6 μm at the peak.

31. The coating composition of claim 26, wherein at least 80% w/w of the total amount of the electron donor dye precursor has a solubility of higher than about 10 g/100 g of ethyl acetate.

32. The coating composition of claim 26, wherein the electron donor dye precursor comprises a compound represented by formula (1): 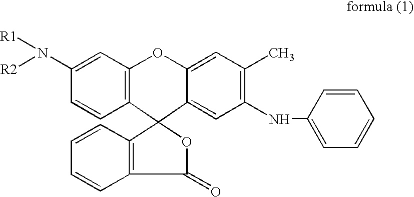
wherein R1 and R2 are each independently selected from hydrogen, C₁-C₈ alkyl, unsubstituted or C₁-C₄ alkyl- or halogen-substituted C₄-C₇ cycloalkyl, unsubstituted phenyl or C₁-C₄ alkyl-, hydroxyl- or halogen-substituted phenyl, C₃-C₆ alkenyl, C₁-C₄ alkoxy, phenyl-C₁-C₄ alkyl, C₁-C₄ alkoxy-C₁-C₄ alkyl and 2-tetrahydrofuranyl, or R1 and R2 together with a linking nitrogen atom form an unsubstituted or C₁-C₄ alkyl-substituted pyrrolidino, piperidino, morpholino, thiomorpholino or piperazino ring.

33. The coating composition of claim 26, wherein the electron donor dye precursor comprises a compound represented by formula (2):

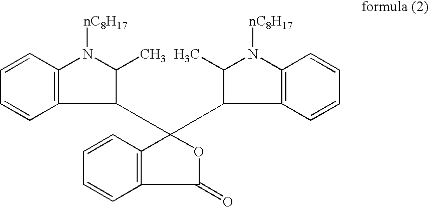

34. The coating composition of claim 26, wherein the electron donor dye precursor comprises a compound represented by formula (3):

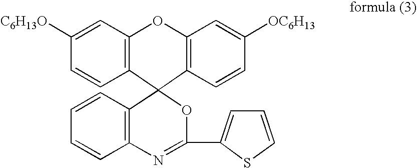

35. A laser-markable material comprising a coating layer, wherein the coating layer comprises electron donor dye precursor particles encapsulated with a polymer having a glass transition temperature, T_{g}, of from about 150° C. to about 190° C., wherein at least 90% of the total volume of the dye precursor particles have a diameter from about 0.2 μm to about 5 μm.

36. The laser-markable material of claim 35, wherein at least 70% w/w of the total amount of the electron donor dye precursor in the coating layer has a solubility of higher than about 10 g/100 g of ethyl acetate.

37. The laser-markable material of claim 35, wherein the coating layer is formed from a coating composition having a viscosity of from about 5 cp to about 30 cp.

38. The laser-markable material of claim 35, wherein the polymer having a T_{g} from about 150° C. to about 190° C. comprises a polyurethane.

39. The laser-markable material of claim 35, wherein the laser-markable material is capable of being marked with a CO₂ laser beam having a wavelength of about 10.6 μm at the peak.

40. The laser-markable material of claim 35, wherein at least 80% w/w of the total amount of the electron donor dye precursor in the coating layer has a solubility of higher than about 10 g/100 g of ethyl acetate.

41. The laser-markable material of claim 35, wherein the electron donor dye precursor comprises a compound represented by formula (1): 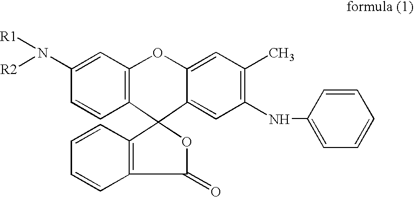
wherein R1 and R2 are each independently selected from hydrogen, C₁-C₈ alkyl, unsubstituted or C₁-C₄ alkyl- or halogen-substituted C₄-C₇ cycloalkyl, unsubstituted phenyl or C₁-C₄ alkyl-, hydroxyl- or halogen-substituted phenyl, C₃-C₆ alkenyl, C₁-C₄ alkoxy, phenyl-C₁-C₄ alkyl, C₁-C₄ alkoxy-C₁-C₄ alkyl and 2-tetrahydrofuranyl, or R1 and R2 together with a linking nitrogen atom form an unsubstituted or C₁-C₄ alkyl-substituted pyrrolidino, piperidino, morpholino, thiomorpholino or piperazino ring.

42. The laser-markable material of claim 35, wherein the electron donor dye precursor comprises a compound represented by formula (2):

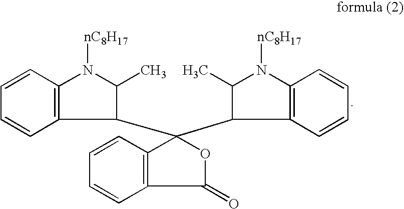

43. The laser-markable material of claim 35, wherein the electron donor dye precursor comprises a compound represented by formula (3):

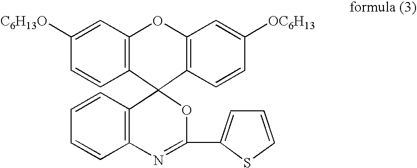

44. The laser-markable material of claim 35, further comprising a substrate on which the coating layer is disposed.

45. The laser-markable material of claim 35, further comprising a protective layer disposed above the coating layer, wherein the protective layer permits passage of a laser beam therethrough that is effective to form a mark upon exposure to the coating layer.

46. The laser-markable material of claim 35, further comprising a protective layer disposed above the coating layer, wherein the protective layer is substantially transparent to a laser beam that is effective to form a mark upon exposure to the coating layer.

47. A method of marking a laser-markable material, comprising exposing the laser-markable material of claim 35 to a laser beam.

48. A composition for forming a laser-markable coating, comprising:
(a) a first component of a color-forming agent, wherein upon exposure to a laser the first component is capable of reacting with a second component of the color-forming agent to generate a color; and
(b) a binder comprising a substituted or unsubstituted polyurethane compound.

49. The composition according to claim 48, wherein the composition further comprises the second component of the color-forming agent.

50. The composition according to claim 48, wherein the substituted or unsubstituted polyurethane compound is selected from the group consisting of a polyester-derived polyurethane, a polyether-derived polyurethane, a polycarbonate-derived polyurethane, a castor oil-derived polyurethane and a combination thereof.

51. The composition according to claim 48, wherein the polyurethane compound is present in an amount of at least about 50% by weight of the binder.

52. The composition according to claim 48, wherein the polyurethane compound is present in an amount of at least about 80% by weight of the binder.

53. The composition according to claim 48, wherein the polyurethane compound is a waterborne polyurethane compound.

54. The composition according to claim 48, wherein the first component is an electron donor dye precursor or an electron acceptor developer.

55. The composition according to claim 54, wherein the first component is an electron donor dye precursor comprising a fluorene series compound.

56. The composition according to claim 54, wherein the electron donor dye precursor has a solubility of greater than about 10 g/100 g in ethyl acetate.

57. The composition according to claim 48, wherein the first component is contained in a plurality of microencapsulated particles.

58. The composition according to claim 57, wherein the microencapsulated particles have a glass transition temperature of from about 150 degrees C. to about 190 degrees C.

59. The composition according to claim 57, wherein the microencapsulated particles have an average particle size of from about 0.2 μm to about 2 μm.

60. The composition according to claim 54, wherein the first component is an electron acceptor developer comprising a metal salt of salicylate.

61. The composition according to claim 60, wherein the electron acceptor developer is a zinc salicylate.

62. A laser-markable material comprising a coating formed from the composition according to claim 48.

63. A laser-markable material, comprising:
(a) a coating comprising a substituted or unsubstituted polyurethane compound; and
(b) a laser-markable layer comprising a color-forming agent, wherein the coating is in contact with the laser-markable layer.

64. A process for forming a marking by laser exposure, comprising applying the composition of claim 48 to a substrate to form a coating, and exposing at least a part of the coating to a laser.

65. The process according to claim 64, wherein at least a part of the coating is exposed to a CO₂ laser.

66. A process for forming a marking by laser exposure, comprising combining the coating composition of claim 48 with a second composition comprising the second component, applying the resulting composition to a substrate to form a coating, and exposing at least a part of the coating to a laser.

67. The process according to claim 66, wherein at least a part of the coating is exposed to a CO₂ laser.
